(19) United States
(12) Patent Application Publication
(10) Pub. No.: US 2025/0380433 A1
(43) Pub. Date: Dec. 11, 2025

(54) SEMICONDUCTOR DEVICE AND SIGNAL TRANSMISSION DEVICE

(71) Applicant: ROHM CO., LTD., Kyoto (JP)

(72) Inventor: Akira TODA, Kyoto (JP)

(73) Assignee: ROHM CO., LTD., Kyoto (JP)

(21) Appl. No.: 19/222,860

(22) Filed: May 29, 2025

(30) Foreign Application Priority Data
Jun. 5, 2024 (JP) 2024-091684

(51) Int. Cl. H10D 1/20; H01L 23/00; H01L 23/31; H01L 23/495; H10D 1/00

(52) U.S. Cl. CPC H10D 1/20; H01L 23/3107; H01L 23/49575; H01L 24/48; H10D 1/01; H01L 2224/48137; H01L 2224/48245; H01L 2924/1206

(57) ABSTRACT

An insulating chip includes a first via and a second via provided within an insulating body. The insulating body includes an insulating layer in which the first via is embedded, and an insulating layer in which the second via is embedded. Both insulating layers include a thin insulating layer made of a material having a smaller coefficient of thermal expansion than each of the first via and the second via, and a thick insulating layer laminated on the thin insulating layer and made of a material having a smaller coefficient of thermal expansion than the thin insulating layer. A lower surface of the second via includes an extending portion that protrudes beyond an upper surface of the first via in plan view. An end portion of the extending portion is in contact with the thick insulating layer of the insulating layer.

### CROSS REFERENCE TO RELATED APPLICATION

This application is based upon and claims the benefit of priority of the prior Japanese Patent Application No. 2024-091684, filed on Jun. 5, 2024, the entire contents of which are incorporated herein by reference.

### TECHNICAL FIELD

The present disclosure relates to a semiconductor device and a signal transmission device.

### BACKGROUND ART

Conventionally, signal transmission devices that transmit a pulse signal while insulating between input and output are used in various applications such as power supply devices and motor drive devices. One example of a signal transmission device is an insulating-type gate driver that applies a gate voltage to the lower side of a switching element such as a transistor. As an example of an insulating chip used in such a gate driver, a structure including a coil formed within a laminated insulating layer structure is known (see, for example, Japanese Unexamined Patent Application Publication JP 2018-78169 A).

### BRIEF DESCRIPTION OF THE DRAWINGS

FIG. 1 is a schematic circuit diagram of an exemplary signal transmission device according to the first embodiment.

FIG. 2 is a schematic plan view schematically showing the configuration of the signal transmission device of FIG. 1.

FIG. 3 is a schematic cross-sectional view of the signal transmission device cut along line F3-F3 in FIG. 2.

FIG. 4 is a schematic perspective view showing an insulating chip of the first embodiment.

FIG. 5 is a schematic plan view of the insulating chip of FIG. 4.

FIG. 6 is a schematic cross-sectional view showing a first coil of the insulating chip of FIG. 5.

FIG. 7 is a schematic cross-sectional view showing a second coil of the insulating chip of FIG. 5.

FIG. 8 is a schematic cross-sectional view of the insulating chip cut along line F8-F8 in FIG. 5.

FIG. 9 is a schematic cross-sectional view of the insulating chip cut along line F9-F9 in FIG. 5.

FIG. 10 is a schematic enlarged cross-sectional view of a through wiring and its periphery of the insulating chip of FIG. 8.

FIG. 11 is a schematic enlarged cross-sectional view of a portion of each of a first via and a second via in the through wiring of FIG. 10.

FIG. 12 is a schematic cross-sectional view for explaining a manufacturing process of the through wiring of FIG. 10.

FIG. 13 is a schematic cross-sectional view showing a manufacturing process following FIG. 12.

FIG. 14 is a schematic cross-sectional view showing a manufacturing process following FIG. 13.

FIG. 15 is a schematic cross-sectional view showing a manufacturing process following FIG. 14.

FIG. 16 is a schematic cross-sectional view showing a manufacturing process following FIG. 15.

FIG. 17 is a schematic cross-sectional view showing a manufacturing process following FIG. 16.

FIG. 18 is a schematic cross-sectional view showing a manufacturing process following FIG. 17.

FIG. 19 is a schematic cross-sectional view showing a manufacturing process following FIG. 18.

FIG. 20 is a schematic cross-sectional view showing a manufacturing process following FIG. 19.

FIG. 21 is a schematic cross-sectional view of a through wiring and its periphery in an insulating chip of a comparative example.

FIG. 22 is a schematic enlarged cross-sectional view of a portion of each of a first via and a second via in FIG. 21.

FIG. 23 is a schematic cross-sectional view of a through wiring and its periphery in an insulating chip of a second embodiment.

FIG. 24 is a schematic enlarged cross-sectional view of a portion of each of a first via and a second via in FIG. 22.

FIG. 25 is a schematic circuit diagram of a signal transmission device of a third embodiment.

FIG. 26 is a schematic cross-sectional view of an insulating chip in the signal transmission device of FIG. 25.

FIG. 27 is a schematic cross-sectional view of a through wiring and its periphery in an insulating chip of a modification example.

FIG. 28 is a schematic cross-sectional view of a through wiring and its periphery in an insulating chip of a modification example.

FIG. 29 is a schematic cross-sectional view of a through wiring and its periphery in an insulating chip of a modification example.

FIG. 30 is a schematic cross-sectional view of a portion of each of a first via and a second via in the through wiring of the insulating chip of a modification example.

FIG. 31 is a schematic cross-sectional view of a portion of each of a first via and a second via in the through wiring of the insulating chip of a modification example.

FIG. 32 is a schematic cross-sectional view of a portion of each of a first via and a second via in the through wiring of the insulating chip of a modification example.

FIG. 33 is a schematic cross-sectional view of a portion of each of a first via and a second via in the through wiring of the insulating chip of a modification example.

FIG. 34 is a schematic plan view of the insulating chip of a modification example.

FIG. 35 is a schematic plan view schematically showing the configuration of a signal transmission device of a modification example.

### DETAILED DESCRIPTION OF EMBODIMENTS

Hereinafter, several embodiments of the semiconductor device and the signal transmission device of the present disclosure will be described with reference to the accompanying drawings. It should be noted that, for simplicity and clarity of explanation, the components shown in the drawings are not necessarily depicted to scale. In addition, in cross-sectional views, hatching lines may be omitted for ease of understanding. The accompanying drawings merely illustrate embodiments of the present disclosure and should not be construed as limiting the disclosure.

The following detailed description includes devices, systems, and methods that embody exemplary embodiments of the present disclosure. This detailed description is intended solely for explanatory purposes and is not intended to limit the embodiments of the present disclosure or the application and use of such embodiments.

Terms such as “first,” “second,” and “third” as used in the present disclosure are merely labels and are not intended to impose any particular order on the referenced elements.

The expression “at least one” as used in the present disclosure means “one or more” of the desired options. For example, when two options exist, “at least one” may mean “only one option” or “both options.” When three or more options exist, “at least one” may mean “only one option” or “any combination of two or more options.”

The expression “dimension (width, length) of A is equal to the dimension (width, length) of B” or “the dimension (width, length) of A and the dimension (width, length) of B are equal to each other” as used in the present disclosure includes the relationship in which the difference between the dimension (width, length) of A and that of B is, for example, within 10% of the dimension (width, length) of A.

### First Embodiment

### [Overall Configuration of Semiconductor Module]

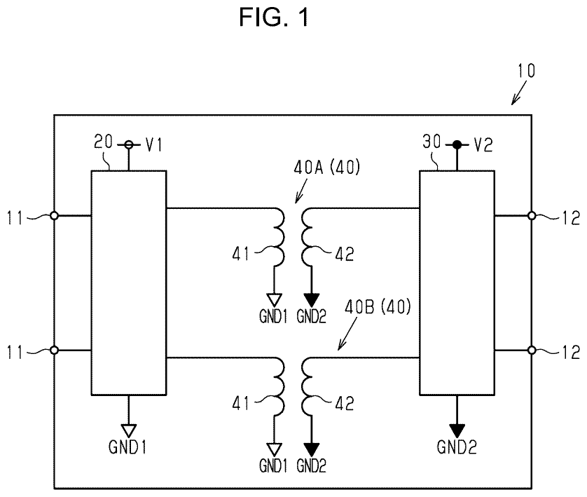

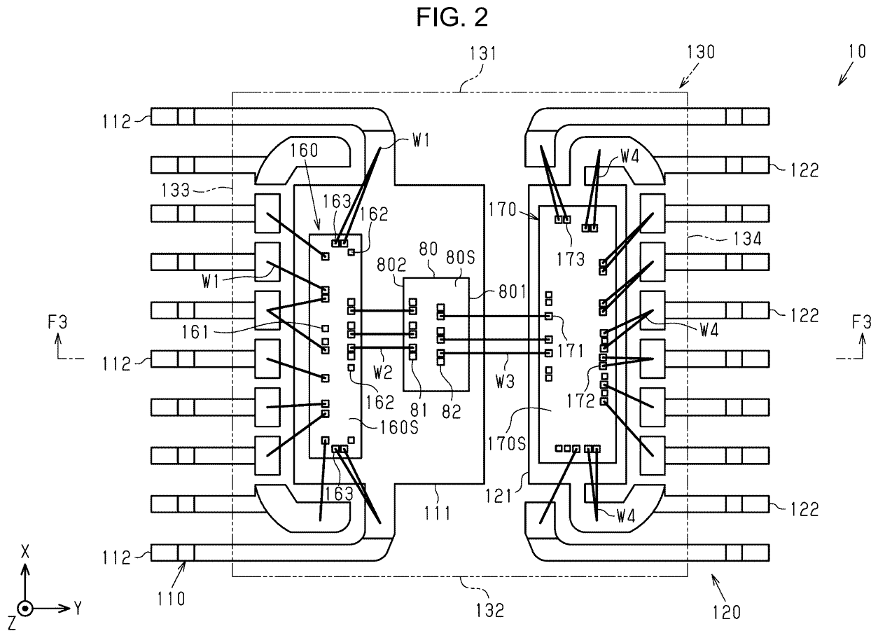

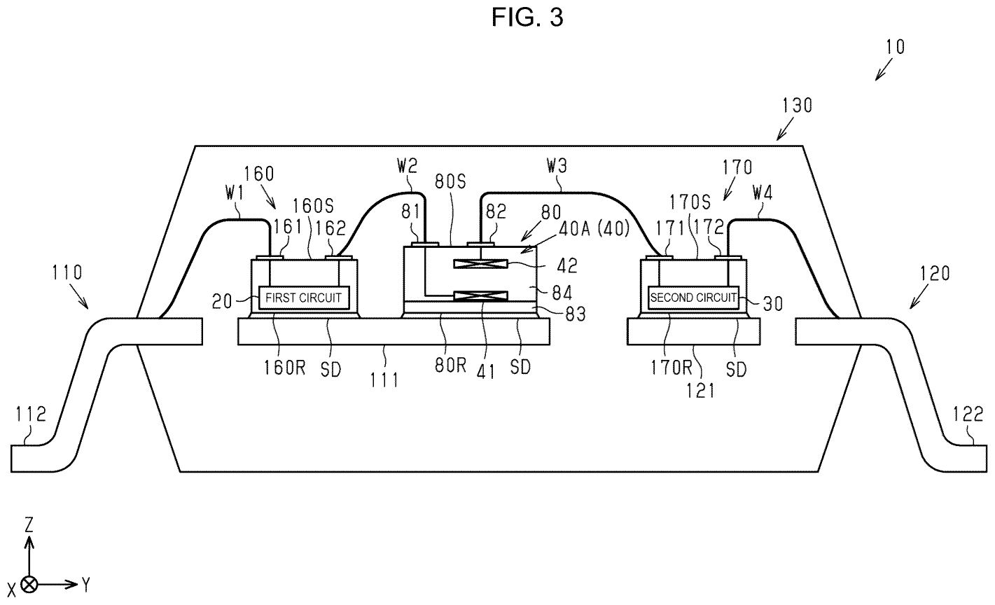

The overall configuration of a signal transmission device 10 as a semiconductor module of the first embodiment will be described with reference to FIGS. 1 to 3. FIG. 1 schematically shows an example of the circuit configuration of the signal transmission device 10. FIG. 2 shows an example of a planar structure schematically showing the internal structure of the signal transmission device 10. FIG. 3 shows an example of a cross-sectional structure schematically showing a part of the internal configuration of the signal transmission device 10. In FIG. 3, hatching lines are omitted for ease of understanding.

As shown in FIG. 1, a signal transmission device 10 includes a plurality of first terminals 11 and a plurality of second terminals 12. The plurality of first terminals 11 and the plurality of second terminals 12 are external terminals that are electrically connected to wiring on a circuit board when the signal transmission device 10 is mounted on a circuit board (not shown). The plurality of first terminals 11 and the plurality of second terminals 12 are used as signal input and output terminals (input terminals and output terminals), power supply terminals for supplying drive power, ground terminals, and the like in the signal transmission device 10. The signal transmission device 10 is a device that transmits a signal between the first terminal 11 and the second terminal 12 used as the input and output terminals while electrically insulating them from each other. The signal transmission device 10 is, for example, a digital isolator.

The signal transmission device 10 includes a first circuit 20 electrically connected to the first terminal 11, a second circuit 30 electrically connected to the second terminal 12, and a transformer 40 connected between the first circuit 20 and the second circuit 30.

The first circuit 20 is a circuit configured to operate when a first voltage V1 is applied. The first circuit 20 is, for example, electrically connected to an external control device (not shown). The second circuit 30 is a circuit configured to operate when a second voltage V2 is applied. In one example, the second voltage V2 may be a voltage different from the first voltage V1. In one example, the second voltage V2 may be a voltage higher than the first voltage V1. Alternatively, the second voltage V2 may be a voltage lower than the first voltage V1. The second voltage V2 may also be equal to the first voltage V1. The first voltage V1 and the second voltage V2 are direct current voltages. The second circuit 30 is electrically connected, for example, to a drive circuit that is controlled by the control device. One example of the drive circuit is a switching circuit. The second circuit 30 may include the drive circuit.

In the signal transmission device 10, the ground of the second circuit 30 and the ground of the first circuit 20 are independently provided. In one example, the respective potentials of the ground of the first circuit 20 and the ground of the second circuit 30 may be used as reference potentials. That is, the potential of the ground GND1 of the first circuit 20 may be the first reference potential, and the potential of the ground GND2 of the second circuit 30 may be the second reference potential. The first voltage V1 is a voltage from the first reference potential, and the second voltage V2 is a voltage from the second reference potential.

The signal transmission device 10 shown in FIG. 1 is configured to output two signals from the first circuit 20 toward the second circuit 30. The transformer 40 includes two transformers 40A and 40B corresponding to the two signals.

Each of the transformers 40A and 40B includes a first coil 41 and a second coil 42. The first coil 41 and the second coil 42 of each of the transformers 40A and 40B are electrically insulated from each other and configured to allow magnetic coupling. Accordingly, it can be said that the first circuit 20 and the second circuit 30 are electrically insulated from each other. It can also be said that the first circuit 20 and the second circuit 30 are connected so that signal transmission is enabled through magnetic coupling of the first coil 41 and the second coil 42 of the transformers 40A and 40B.

The first coil 41 of each of the transformers 40A and 40B is electrically connected to the first circuit 20. The second coil 42 of each of the transformers 40A and 40B is electrically connected to the second circuit 30. In one example, a control signal from a control device is input to the first circuit 20 through the first terminal 11. The first circuit 20 outputs a transmission signal to the second circuit 30 in accordance with the control signal. The transmission signal is received by the second circuit 30 via the transformers 40A and 40B. The second circuit 30 outputs a signal corresponding to the received signal, such as a gate drive signal, to a drive circuit through the second terminal 12. Alternatively, the second circuit 30 may be configured to output a signal toward the first circuit 20, and the first circuit 20 may be configured to receive the signal. Further, each of the first circuit 20 and the second circuit 30 may be configured to transmit and receive signals.

As described above, in the signal transmission device 10, the first circuit 20 and the second circuit 30 are electrically insulated from each other by the transformer 40. More specifically, the transformer 40 restricts transmission of direct current voltage between the first circuit 20 and the second circuit 30. On the other hand, the transformer 40 allows transmission of pulse signals between the first circuit 20 and the second circuit 30. The transformer 40 is an insulating element that electrically insulates the second circuit 30 from the first circuit 20 and transmits signals between the second circuit 30 and the first circuit 20.

That is, the state in which the first circuit 20 and the second circuit 30 are insulated refers to a state in which transmission of direct current voltage between the first circuit 20 and the second circuit 30 is blocked, while allowing transmission of pulse signals from the first circuit 20 to the second circuit 30. In this way, in the first embodiment, the second circuit 30 is configured to receive signals from the first circuit 20.

The first circuit 20 and the second circuit 30 may be referred to as a primary-side circuit and a secondary-side circuit, respectively, with respect to the transformer 40. In one example, the second circuit 30 is the secondary-side circuit, and the first circuit 20 is the primary-side circuit. Alternatively, the second circuit 30 may be the primary-side circuit, and the first circuit 20 may be the secondary-side circuit. Each of the second circuit 30 and the first circuit 20 may include both a primary-side circuit and a secondary-side circuit.

As shown in FIGS. 2 and 3, the signal transmission device 10 includes a first support member 110, a second support member 120, an insulating chip 80, a first circuit chip 160, a second circuit chip 170, and a sealing resin 130. The first circuit chip 160 and the insulating chip 80 are mounted on the first support member 110. The second circuit chip 170 is mounted on the second support member 120. As such, the signal transmission device 10 is a semiconductor module in which the first circuit chip 160, the second circuit chip 170, and the insulating chip 80 are packaged. The insulating chip 80 includes the transformers 40A and 40B shown in FIG. 1. The first circuit chip 160 includes the first circuit 20 shown in FIG. 1. The second circuit chip 170 includes the second circuit 30 shown in FIG. 1. The configuration of the signal transmission device 10 may be arbitrarily modified. In one example, the signal transmission device 10 may include chips other than the first circuit chip 160, the second circuit chip 170, and the insulating chip 80. Here, the insulating chip 80 corresponds to the “semiconductor device.”

The package type of the signal transmission device 10 is a Small Outline (SO) type, and in one example, a Small Outline Package (SOP). The package type of the signal transmission device 10 may be arbitrarily modified. The package type of the signal transmission device 10 is not limited to SOP and may be a Quad Flat No-lead (QFN) package, Dual Flat Package (DFP), Dual Inline Package (DIP), Small Outline J-leaded (SOJ) package, or various other package types similar to these.

The sealing resin 130 seals the first circuit chip 160, the second circuit chip 170, and the insulating chip 80, and also partially seals the first support member 110 and the second support member 120. In FIG. 2, the sealing resin 130 is indicated by a two-dot chain line for the purpose of explaining the internal structure of the signal transmission device 10.

The sealing resin 130 is formed of a resin material having electrical insulation properties. As this resin material, a resin including epoxy resin may be used, for example. The resin may be colored black or another color. The sealing resin 130 is in the form of a rectangular plate with the Z direction as the thickness direction. The sealing resin 130 includes four resin side surfaces 131 to 134. The resin side surfaces 131 and 132 form the opposite end surfaces of the sealing resin 130 in the X direction. The resin side surfaces 133 and 134 form the opposite end surfaces of the sealing resin 130 in the Y direction. Here, the X direction and the Y direction are directions orthogonal to the Z direction. The X direction and the Y direction are orthogonal to each other. In the following description, the term “plan view” refers to viewing the signal transmission device 10 or components thereof from the Z direction.

Each of the first support member 110 and the second support member 120 is electrically conductive. The first support member 110 and the second support member 120 are each formed of a conductive material including Cu (copper), Fe (iron), Al (aluminum), or the like. The first support member 110 and the second support member 120 are each provided so as to straddle the inside and outside of the sealing resin 130.

The first support member 110 includes a first die pad 111 disposed within the sealing resin 130 and a plurality of first lead terminals 112 disposed to straddle the inside and outside of the sealing resin 130. The first die pad 111 is a flat plate with the Z direction as the thickness direction. In plan view, the first die pad 111 is disposed such that its center in the Y direction is closer to the resin side surface 133 than the center of the sealing resin 130 in the Y direction. The first die pad 111 is not exposed from the sealing resin 130. In one example, the first die pad 111 has a rectangular shape in plan view, in which the X direction is the long-side direction and the Y direction is the short-side direction. The shape of the first die pad 111 in plan view may be arbitrarily modified.

The plurality of first lead terminals 112 are arranged with spacing between them in the X direction. Each of the first lead terminals 112 disposed at both ends in the X direction among the plurality of first lead terminals 112 is integrated with the first die pad 111. A portion of each of the first lead terminals 112 protrudes outward from the sealing resin 130 through the resin side surface 133. The plurality of first lead terminals 112 are external terminals of the signal transmission device 10 and correspond to the first terminals 11 in FIG. 1. Here, in FIG. 1, the circuit configuration of the signal transmission device 10 is shown in a simplified manner, so the number of first lead terminals 112 shown in FIG. 2 is greater than the number of first terminals 11 shown in FIG. 1.

The second support member 120 includes a second die pad 121 disposed within the sealing resin 130 and a plurality of second lead terminals 122 disposed to straddle the inside and outside of the sealing resin 130. The second die pad 121 is a flat plate with the Z direction as the thickness direction. In plan view, the second die pad 121 is disposed closer to the resin side surface 134 than the first die pad 111. The second die pad 121 is not exposed from the sealing resin 130. In one example, the second die pad 121 has a rectangular shape in plan view, in which the X direction is the long-side direction and the Y direction is the short-side direction.

The first die pad 111 and the second die pad 121 are arranged with a space between them in the Y direction. Therefore, the Y direction can be considered as the arrangement direction of the first die pad 111 and the second die pad 121.

The Y-direction dimension of the first die pad 111 and the second die pad 121 is set according to the size and number of semiconductor chips to be mounted. In the first embodiment, both the first circuit chip 160 and the insulating chip 80 are mounted on the first die pad 111, and the second circuit chip 170 is mounted on the second die pad 121. Therefore, the Y-direction dimension of the first die pad 111 is set to be greater than the Y-direction dimension of the second die pad 121.

The plurality of second lead terminals 122 are arranged with spacing between them in the X direction. Two of the plurality of second lead terminals 122 are integrated with the second die pad 121. A portion of each of the second lead terminals 122 protrudes outward from the sealing resin 130 through the resin side surface 134. The plurality of second lead terminals 122 are external terminals of the signal transmission device 10 and correspond to the second terminals 12 in FIG. 1. Here, in FIG. 1, the circuit configuration of the signal transmission device 10 is shown in a simplified manner, so the number of second lead terminals 122 shown in FIG. 2 is greater than the number of second terminals 12 shown in FIG. 1.

In the first embodiment, the number of second lead terminals 122 is equal to the number of first lead terminals 112. As can be seen from FIG. 2, the plurality of first lead terminals 112 and the plurality of second lead terminals 122 are arranged in a direction (X direction) orthogonal to the arrangement direction (Y direction) of the first die pad 111 and the second die pad 121. The number of second lead terminals 122 and the number of first lead terminals 112 may each be arbitrarily modified.

The first support member 110 and the second support member 120 are each formed from a lead frame (not shown). During the manufacturing process of the signal transmission device 10, the first die pad 111, the plurality of first lead terminals 112, the second die pad 121, and the plurality of second lead terminals 122 are formed from the same lead frame.

The lead frame includes an outer frame formed to surround the first support member 110 and the second support member 120. The first lead terminals 112 and the second lead terminals 122 are connected to the outer frame. During the manufacturing process of the signal transmission device 10, the first lead terminals 112 and the second lead terminals 122 are formed by being cut off from the outer frame.

The first die pad 111 is integrated with two of the first lead terminals 112. The first die pad 111 is supported by the two first lead terminals 112 integrated with the first die pad 111. The second die pad 121 is integrated with two of the second lead terminals 122. The second die pad 121 is supported by the two second lead terminals 122 integrated with the second die pad 121. Therefore, the first die pad 111 and the second die pad 121 are not provided with suspension leads exposed from the resin side surfaces 131 and 132. Accordingly, a large insulation distance (creepage distance) can be secured between the first support member 110 and the second support member 120.

The first die pad 111 may be supported by one of the first lead terminals 112. Similarly, the second die pad 121 may be supported by one of the second lead terminals 122.

The first circuit chip 160 and the insulating chip 80 mounted on the first die pad 111 and the second circuit chip 170 mounted on the second die pad 121 are arranged with spacing between them in the Y direction. In the Y direction from the first lead terminal 112 toward the second lead terminal 122, the first circuit chip 160, the insulating chip 80, and the second circuit chip 170 are arranged in this order. Therefore, it can be said that the Y direction is the arrangement direction of the first circuit chip 160, the insulating chip 80, and the second circuit chip 170. The insulating chip 80 is disposed between the first circuit chip 160 and the second circuit chip 170 in the Y direction.

The first circuit chip 160 has a rectangular shape in plan view with short sides and long sides. In one example, the first circuit chip 160 is mounted on the first die pad 111 such that the long side extends along the X direction and the short side extends along the Y direction.

As shown in FIG. 3, the first circuit chip 160 includes a chip front surface 160S and a chip rear surface 160R, which face opposite directions in the Z direction. The chip rear surface 160R is bonded to the first die pad 111 via a conductive bonding material SD. The conductive bonding material SD may be, for example, solder or Ag (silver) paste.

As shown in FIG. 2, a plurality of first electrode pads 161, a plurality of second electrode pads 162, and a plurality of third electrode pads 163 are provided on the chip front surface 160S of the first circuit chip 160. At least one of the plurality of first electrode pads 161, at least one of the plurality of second electrode pads 162, and at least one of the plurality of third electrode pads 163 is electrically connected to the first circuit 20 shown in FIG. 1.

The plurality of first electrode pads 161 are disposed on the chip front surface 160S closer to the first lead terminal 112 than to the center of the chip front surface 160S in the Y direction. In one example, the plurality of first electrode pads 161 are arranged in the X direction. The plurality of second electrode pads 162 are disposed at the end of the chip front surface 160S in the Y direction that is closer to the insulating chip 80. The plurality of second electrode pads 162 are arranged in the X direction. The plurality of third electrode pads 163 are disposed at both ends of the chip front surface 160S in the X direction.

The second circuit chip 170 has a rectangular shape in plan view with short sides and long sides. The second circuit chip 170 is mounted on the second die pad 121 such that the long side extends along the X direction and the short side extends along the Y direction.

As shown in FIG. 3, the second circuit chip 170 includes a chip front surface 170S and a chip rear surface 170R, which face opposite directions in the Z direction. The chip rear surface 170R is bonded to the second die pad 121 via a conductive bonding material SD.

As shown in FIG. 2, a plurality of first electrode pads 171, a plurality of second electrode pads 172, and a plurality of third electrode pads 173 are provided on the chip front surface 170S of the second circuit chip 170. At least one of the plurality of first electrode pads 171, at least one of the plurality of second electrode pads 172, and at least one of the plurality of third electrode pads 173 is electrically connected to the second circuit 30 shown in FIG. 1.

The plurality of first electrode pads 171 are disposed at the end of the chip front surface 170S in the Y direction that is closer to the insulating chip 80. The plurality of first electrode pads 171 are arranged in the X direction. The plurality of second electrode pads 172 are disposed at the end of the chip front surface 170S in the Y direction that is farther from the insulating chip 80. That is, the plurality of second electrode pads 172 are disposed at the end of the chip front surface 170S in the Y direction that is closer to the second lead terminal 122. The plurality of second electrode pads 172 are arranged in the X direction. The plurality of third electrode pads 173 are disposed at both ends of the chip front surface 170S in the X direction.

The insulating chip 80 has a rectangular shape in plan view with short sides and long sides. The insulating chip 80 is mounted on the first die pad 111 such that the long side extends along the X direction and the short side extends along the Y direction. In one example, the X-direction dimension of the insulating chip 80 is smaller than that of the first circuit chip 160. In one example, the X-direction dimension of the insulating chip 80 is smaller than that of the second circuit chip 170. The X-direction dimension of the insulating chip 80 may be arbitrarily modified.

The insulating chip 80 is a semiconductor chip that integrates the transformers 40A and 40B into a single chip. That is, the insulating chip 80 is provided as a semiconductor chip different from the first circuit chip 160 and the second circuit chip 170. The insulating chip 80 is disposed adjacent to the first circuit chip 160 in the Y direction.

As shown in FIG. 3, the insulating chip 80 includes a chip front surface 80S and a chip rear surface 80R, which face opposite directions in the Z direction. The chip rear surface 80R is bonded to the first die pad 111 via a conductive bonding material SD.

As shown in FIG. 2, the insulating chip 80 includes a plurality of first electrode pads 81 and a plurality of second electrode pads 82. The plurality of first electrode pads 81 and the plurality of second electrode pads 82 are provided on the chip front surface 80S of the insulating chip 80. The plurality of first electrode pads 81 are disposed at the end of the chip front surface 80S in the Y direction that is closer to the first circuit chip 160. The plurality of first electrode pads 81 are arranged in the X direction. The plurality of second electrode pads 82 are disposed near the center of the chip front surface 80S in the Y direction. The plurality of second electrode pads 82 are arranged in the X direction.

To ensure that the withstand voltage of the signal transmission device 10 matches a predetermined insulation withstand voltage, it is necessary to provide spacing between the first die pad 111 and the second die pad 121, which are the closest parts of the first support member 110 and the second support member 120. Accordingly, the insulating chip 80 is disposed closer to the second circuit chip 170 than to the first circuit chip 160. In other words, the distance in the Y direction between the insulating chip 80 and the second circuit chip 170 is greater than the distance in the Y direction between the insulating chip 80 and the first circuit chip 160.

The first circuit chip 160, the insulating chip 80, and the second circuit chip 170 are each connected to a plurality of wires W1 to W4. Each wire W1 to W4 is a bonding wire formed by a wire bonding device. Each wire W1 to W4 is made of a conductive material including, for example, Au (gold), Al, or Cu.

The first circuit chip 160 is electrically connected to the first lead terminal 112 via wire W1. More specifically, the plurality of first electrode pads 161 are individually electrically connected to the plurality of first lead terminals 112 via the plurality of wires W1. The plurality of third electrode pads 163 are individually electrically connected to the two first lead terminals 112 integrated with the first die pad 111 via the plurality of wires W1. As a result, the first circuit 20 shown in FIG. 1 is electrically connected to the plurality of first lead terminals 112. The first lead terminals 112 integrated with the first die pad 111 form ground terminals, and the first circuit 20 is electrically connected to the first die pad 111 via the wires W1. Accordingly, the first ground GND1 of the first circuit 20 shown in FIG. 1 has the same potential as the first die pad 111.

The second circuit chip 170 is electrically connected to the second lead terminal 122 via wire W4. More specifically, the plurality of second electrode pads 172 and the plurality of third electrode pads 173 are individually electrically connected to the plurality of second lead terminals 122 via the plurality of wires W4. Some of the plurality of third electrode pads 173 are individually electrically connected to the two second lead terminals 122 integrated with the second die pad 121 via the plurality of wires W4. As a result, the second circuit 30 shown in FIG. 1 is electrically connected to the plurality of second lead terminals 122. The second lead terminals 122 integrated with the second die pad 121 form ground terminals, and the second circuit 30 is electrically connected to the second die pad 121 via the wires W4. Accordingly, the second ground GND2 of the second circuit 30 shown in FIG. 1 has the same potential as the second die pad 121.

The insulating chip 80 is connected to the first circuit chip 160 via wire W2. The insulating chip 80 is also connected to the second circuit chip 170 via wire W3. More specifically, the plurality of first electrode pads 81 of the insulating chip 80 are individually electrically connected to the plurality of second electrode pads 162 of the first circuit chip 160 via the plurality of wires W2. The plurality of second electrode pads 82 of the insulating chip 80 are individually electrically connected to the plurality of first electrode pads 171 of the second circuit chip 170 via the plurality of wires W3.

Both of the first coils 41 of the transformers 40A and 40B shown in FIG. 1 are electrically connected to the first ground GND1 of the first circuit chip 160 via wire W1. Both of the second coils 42 of the transformers 40A and 40B shown in FIG. 1 are electrically connected to the second ground GND2 of the second circuit chip 170 via wire W4.

The configuration of the signal transmission device 10 shown in FIG. 1 is merely an example, and the circuit configurations included in the first circuit chip 160 and the second circuit chip 170 may be modified as appropriate. In one example, the first circuit 20 may include an analog-to-digital conversion circuit. In such a case, the signal transmission device 10 is configured as an insulated A/D converter. In one example, the second circuit 30 may include a driver circuit for driving a gate of a switching element. The driver circuit may be connected to a terminal of the signal transmission device 10. In one example, the driver circuit may be electrically connected to the second lead terminal 122. In this case, the signal transmission device 10 is configured as an insulated gate driver for driving a switching element. The switching element may be a power semiconductor element such as a Si MOSFET (Silicon Metal-Oxide-Semiconductor Field-Effect Transistor), SiC MOSFET, or IGBT (Insulated Gate Bipolar Transistor). The switching element may be used in a motor driver circuit in an inverter device. A half-bridge circuit in which a low-side switching element and a high-side switching element are connected in a totem pole configuration is generally used as the driver circuit.

The signal transmission device 10 used as an insulated gate driver applies a drive voltage signal to the control terminal of a switching element. In this case, the first circuit 20 converts a control signal input from a control device into a pulse signal, for example. The driver circuit of the second circuit 30 outputs a drive voltage signal to the control terminal of the switching element based on the signal received through the transformers 40A and 40B. The first circuit 20 and the second circuit 30 may also be used to transmit a detection signal from a sensor, such as a temperature sensor disposed near a motor, to a control device.

In the signal transmission device 10 used as an insulated gate driver, the first voltage V1 of the first circuit 20, which receives a signal from the control device, is 5 V, 3.3 V, or the like, based on the ground potential. On the other hand, in the case of the second circuit 30 connected to the high-side switching element, a voltage equivalent to the voltage applied to the drain of the high-side switching element (e.g., 600 V or more) is transiently applied. Therefore, the insulation withstand voltage of the signal transmission device 10 ranges from 2500 Vrms to 7500 Vrms. The specific value of the insulation withstand voltage of the signal transmission device 10 is not limited to this range and may be arbitrarily set.

### [Configuration of the Insulating Chip]

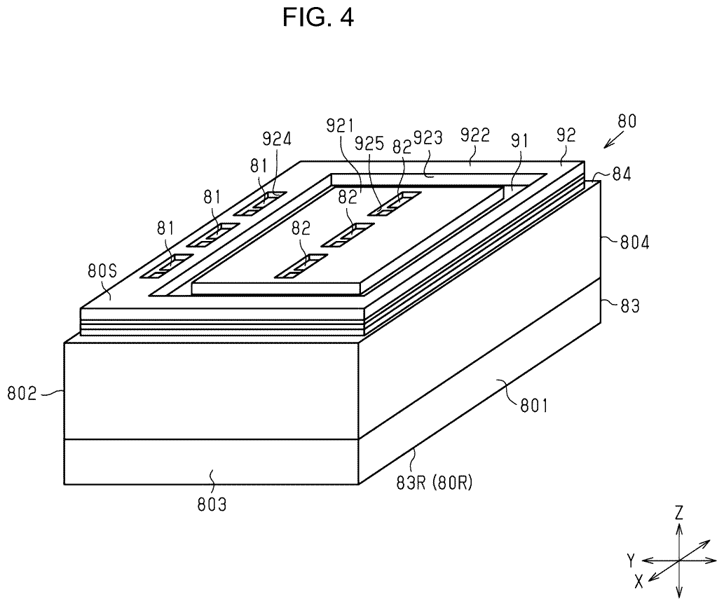

The overall configuration of the insulating chip 80 will be described with reference to FIGS. 4 to 9.

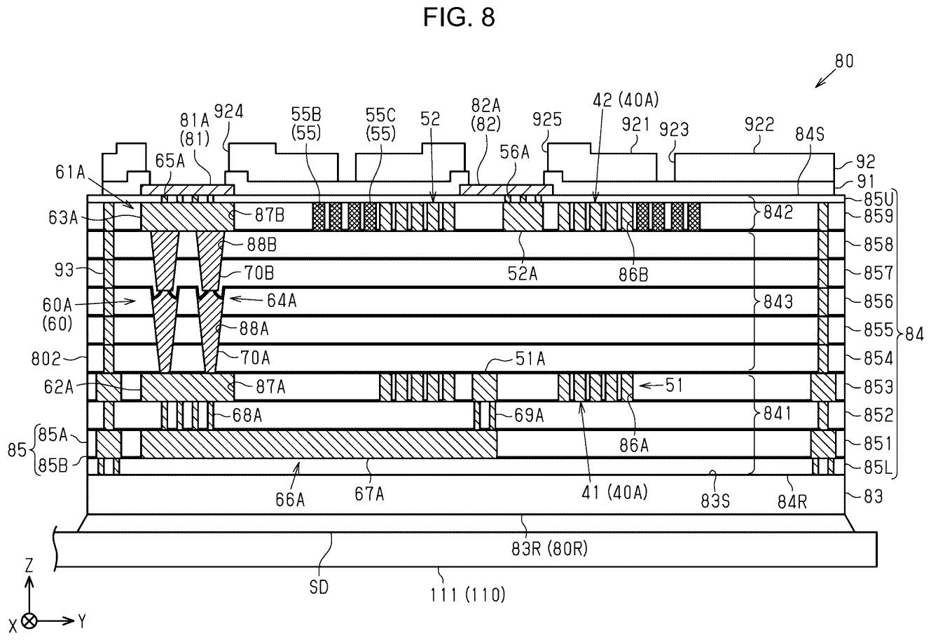

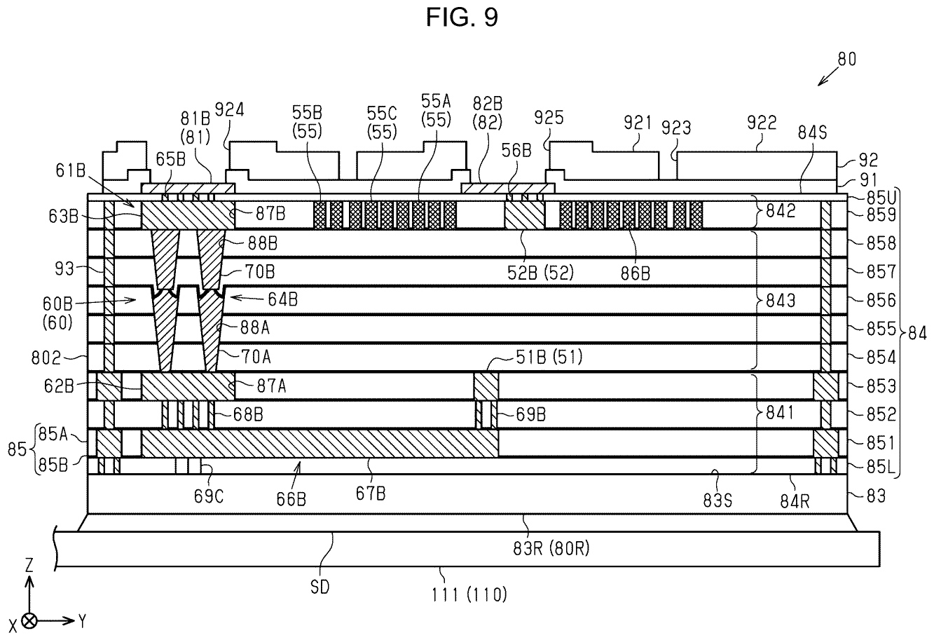

In the following description, the direction from the chip rear surface 80R to the chip front surface 80S of the insulating chip 80 shown in FIGS. 8 and 9 is defined as upward, and the direction from the chip front surface 80S to the chip rear surface 80R is defined as downward.

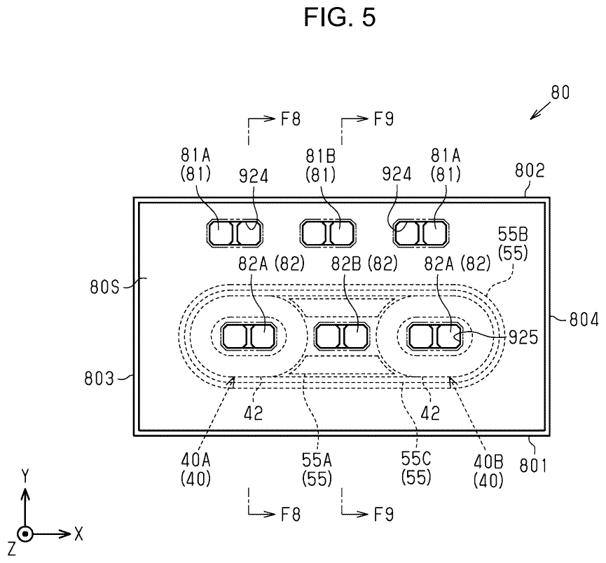

FIG. 4 schematically illustrates a perspective structure of the insulating chip 80. FIG. 5 schematically illustrates a plan structure of the insulating chip 80. In FIG. 5, for convenience of explanation, the transformers 40A and 40B, as well as a dummy pattern 55 described later, are shown with dashed lines. Also in FIG. 5, the first electrode pads 81 and the second electrode pads 82 are shown with two-dot chain lines, and resin openings of a resin layer 92 described later are shown with solid lines.

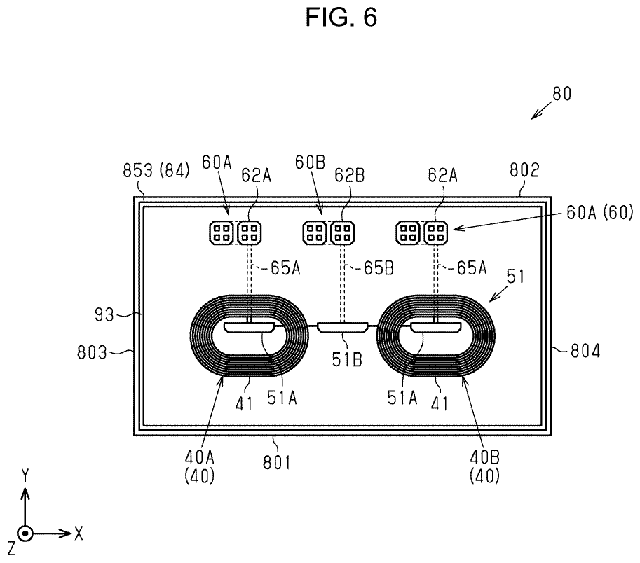

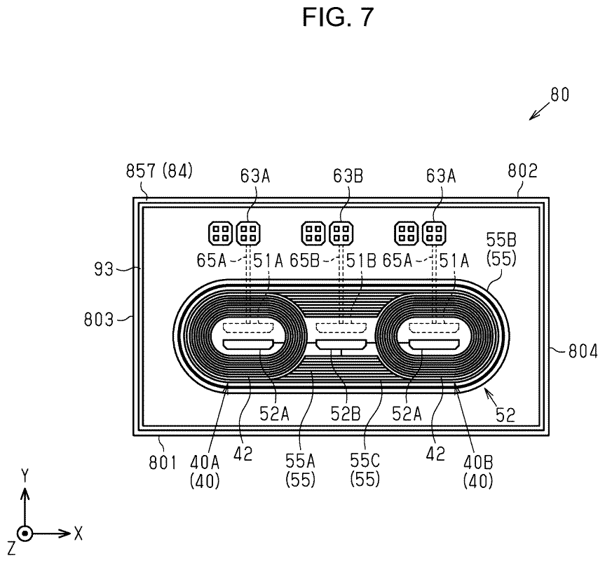

FIG. 6 schematically illustrates a cross-sectional structure in the XY plane taken at a Z-direction position where the first coil 41 of the insulating chip 80 in FIG. 5 is disposed. FIG. 6 primarily shows the connection relationship of the first coil 41. FIG. 7 schematically illustrates a cross-sectional structure in the XY plane taken at a Z-direction position where the second coil 42 of the insulating chip 80 in FIG. 5 is disposed. FIG. 7 primarily shows the connection relationship of the second coil 42. For convenience, hatching lines are omitted in FIGS. 6 and 7.

FIG. 8 schematically illustrates a cross-sectional structure of the insulating chip 80 taken along line F8-F8 in FIG. 5. FIG. 8 schematically illustrates a cross-sectional structure including an insulating body 84, the first coil 41, the second coil 42, the dummy pattern 55, the first electrode pad 81, the second electrode pad 82, and a first connection wiring 60A described later. FIG. 9 schematically illustrates a cross-sectional structure of the insulating chip 80 taken along line F9-F9 in FIG. 5. FIG. 9 schematically illustrates a cross-sectional structure including the insulating body 84, the dummy pattern 55, the first electrode pad 81, the second electrode pad 82, and a second connection wiring 60B described later.

As shown in FIG. 5, the transformers 40A and 40B are disposed near the center of the chip front surface 80S in the Y direction in plan view. In one example, in plan view, the plurality of first electrode pads 81 and the transformers 40A and 40B are arranged at positions not overlapping each other. The first electrode pads 81 and the second electrode pads 82 are each electrically connected to the transformers 40A and 40B, respectively.

As shown in FIGS. 4 and 5, the insulating chip 80 includes four chip side surfaces 801 to 804 that connect the chip front surface 80S and the chip rear surface 80R. The chip side surfaces 801 and 802 form the opposite end surfaces in the Y direction of the insulating chip 80. The chip side surfaces 803 and 804 form the opposite end surfaces in the X direction of the insulating chip 80. In plan view, the chip side surfaces 801 and 802 form the long sides of the insulating chip 80, and the chip side surfaces 803 and 804 form the short sides of the insulating chip 80. As shown in FIG. 2, the chip side surface 801 is the side closer to the second circuit chip 170 than the chip side surface 802. The chip side surface 802 is the side closer to the first circuit chip 160 than the chip side surface 801.

As shown in FIGS. 4, 8, and 9, the insulating chip 80 includes a substrate 83 and an insulating body 84.

The substrate 83 is formed of, for example, a semiconductor substrate. The substrate 83 is a substrate composed of a material containing Si (silicon). In one example, the substrate 83 is a Si substrate. The Si substrate used for the substrate 83 may include, for example, a semiconductor substrate composed of intrinsic single-crystal semiconductor material, a p-type semiconductor substrate containing an acceptor-type impurity, or an n-type semiconductor substrate containing a donor-type impurity.

The substrate 83 may use a wide bandgap semiconductor or compound semiconductor as the semiconductor substrate. Alternatively, instead of a semiconductor substrate, an insulating substrate composed of a material containing glass may be used for the substrate 83. A wide bandgap semiconductor is a semiconductor substrate having a bandgap of 2.0 eV or more. The wide bandgap semiconductor may be SiC (silicon carbide), GaN (gallium nitride), or Ga₂O₃ (gallium oxide), for example. The compound semiconductor may be a group III-V compound semiconductor. The compound semiconductor may include at least one of AlN (aluminum nitride), InN (indium nitride), GaN, and GaAs (gallium arsenide).

The substrate 83 is a flat plate with the Z direction as the thickness direction. The substrate 83 includes a substrate upper surface 83S and a substrate lower surface 83R, which face opposite directions in the Z direction. In one example, the substrate lower surface 83R forms the chip rear surface 80R of the insulating chip 80. In plan view, the substrate 83 has a quadrangular shape. In one example, the substrate 83 has a rectangular shape in which the X direction is the long side and the Y direction is the short side.

As shown in FIGS. 8 and 9, the insulating body 84 is provided on the substrate upper surface 83S of the substrate 83. The insulating body 84 includes an insulating upper surface 84S and an insulating lower surface 84R opposite to the insulating upper surface 84S. In one example, the insulating lower surface 84R is in contact with the substrate upper surface 83S.

The insulating body 84 includes a plurality of insulating layers 85 disposed in the Z direction from the substrate upper surface 83S of the substrate 83. The plurality of insulating layers 85 are laminated on the substrate upper surface 83S of the substrate 83. It can be said that the insulating body 84 includes a plurality of insulating layers 85 laminated in the Z direction from the substrate upper surface 83S. The Z direction is the thickness direction of the insulating body 84. The Z direction is also the lamination direction of the insulating layers 85.

The plurality of insulating layers 85 include a plurality of thick insulating layers 85A and a plurality of thin insulating layers 85B. The insulating body 84 is configured as a laminated insulating stack in which one thick insulating layer 85A and one thin insulating layer 85B are alternately laminated. Both the topmost insulating layer 85U and the bottommost insulating layer 85L among the plurality of insulating layers 85 are composed of thick insulating layers 85A.

The thick insulating layer 85A is, for example, an interlayer insulating film. The thick insulating layer 85A is composed of a material having a smaller coefficient of thermal expansion than each of a first via 70A and a second via 70B described later. In other words, the thick insulating layer 85A is composed of a material having a smaller coefficient of linear expansion than each of the first via 70A and the second via 70B. The thick insulating layer 85A is also composed of a material having a smaller coefficient of linear expansion than each of a first conductor 51 and a second conductor 52 described later. That is, the thick insulating layer 85A is composed of a material having a smaller coefficient of linear expansion than each of the first conductor 51 and the second conductor 52. The thick insulating layer 85A is composed of a material containing SiO (silicon oxide). In one example, the thick insulating layer 85A is composed of a material containing SiO₂. In one example, the thick insulating layer 85A is a SiO₂ film.

The thin insulating layer 85B is a thin film and is, for example, an etching stopper layer. The thin insulating layer 85B is composed of a material having a greater coefficient of thermal expansion than that of the thick insulating layer 85A and a smaller coefficient of thermal expansion than each of the first via 70A and the second via 70B. In other words, the thin insulating layer 85B is composed of a material having a greater coefficient of linear expansion than that of the thick insulating layer 85A and a smaller coefficient of linear expansion than each of the first via 70A and the second via 70B. The thin insulating layer 85B is also composed of a material having a greater coefficient of thermal expansion than that of the thick insulating layer 85A and a smaller coefficient of thermal expansion than each of the first conductor 51 and the second conductor 52. In other words, the thin insulating layer 85B is composed of a material having a greater coefficient of linear expansion than that of the thick insulating layer 85A and a smaller coefficient of linear expansion than each of the first conductor 51 and the second conductor 52. The thin insulating layer 85B is composed of a material including SiN (silicon nitride), SiC, or SiCN (silicon carbon nitride). The thin insulating layer 85B is composed of a material containing SiN. In one example, the thin insulating layer 85B is a SiN film.

The thickness of the thick insulating layer 85A may be 1000 nm or more and 3000 nm or less. In one example, the thickness of the thick insulating layer 85A is approximately 2300 nm. The thickness of the thin insulating layer 85B may be 100 nm or more and less than 1000 nm. In one example, the thickness of the thin insulating layer 85B is approximately 300 nm.

The lower surface of the bottommost insulating layer 85L forms the insulating lower surface 84R of the insulating body 84. The upper surface of the topmost insulating layer 85U forms the insulating upper surface 84S. In one example, the thickness of each of the bottommost insulating layer 85L and the topmost insulating layer 85U is equal to or greater than the thickness of the thin insulating layer 85B and equal to or less than the thickness of the thick insulating layer 85A. The thicknesses of the bottommost insulating layer 85L and the topmost insulating layer 85U may be arbitrarily modified. In one example, the thicknesses of both the bottommost insulating layer 85L and the topmost insulating layer 85U may be greater than that of the thick insulating layer 85A and may also be greater than the thickness of the insulating layer 85 composed of the thick insulating layer 85A and the thin insulating layer 85B.

As shown in FIGS. 6 to 9, the insulating chip 80 includes a first conductor 51 and a second conductor 52 that form the transformers 40A and 40B. In the first embodiment, both the first conductor 51 and the second conductor 52 are coils. The first conductor 51 and the second conductor 52 are embedded in the insulating body 84. The first conductor 51 and the second conductor 52 are provided in different insulating layers 85 within the insulating body 84. The first conductor 51 and the second conductor 52 are opposed to each other in the Z direction.

In the first embodiment, the plurality of insulating layers 85 include insulating layers 851 to 859 provided between the bottommost insulating layer 85L and the topmost insulating layer 85U. Each of the insulating layers 851 to 859 is composed of a thin insulating layer 85B and a thick insulating layer 85A laminated on the thin insulating layer 85B. The insulating layer 851 is in contact with the bottommost insulating layer 85L. The insulating layer 859 is in contact with the topmost insulating layer 85U.

As shown in FIGS. 8 and 9, the first conductor 51 of the transformers 40A and 40B is formed as a conductive layer embedded in one of the insulating layers 85 included in the insulating body 84. The first conductor 51 is embedded in an insulating layer 853, which is closer to the insulating lower surface 84R among the plurality of insulating layers 85 that constitute the insulating body 84. The insulating layer 853 includes a groove 86A that penetrates both the thick insulating layer 85A and the thin insulating layer 85B in the Z direction. The first conductor 51 is embedded in the groove 86A of the insulating layer 853. The first conductor 51 and the insulating layer 853 are covered by an insulating layer 854.

As shown in FIGS. 6, 8, and 9, the first conductor 51 includes a first coil 41, an inner end wiring 51A, and an outer end wiring 51B. Each of the first coil 41, the inner end wiring 51A, and the outer end wiring 51B is formed of a material that includes one or more appropriately selected from Ti (titanium), TiN (titanium nitride), Au, Ag, Cu, Al, and W (tungsten). In one example, the first coil 41, the inner end wiring 51A, and the outer end wiring 51B are formed of the same material. In another example, the first coil 41, the inner end wiring 51A, and the outer end wiring 51B are formed of different materials.

As shown in FIG. 6, the first coil 41 has a spiral shape in plan view. In one example, the first coil 41 has an elliptical shape in plan view. Each of the first coils 41 of the transformers 40A and 40B includes a first end and a second end opposite the first end. The first end is the inner end of the first coil 41, and the second end is the outer end of the first coil 41. The first end of each of the first coils 41 of the transformers 40A and 40B is individually electrically connected to the corresponding inner end wiring 51A. The second end of each of the first coils 41 of the transformers 40A and 40B is electrically connected to the outer end wiring 51B.

The inner end wiring 51A is disposed inside each of the first coils 41 of the transformers 40A and 40B. In the first embodiment, two inner end wirings 51A are provided corresponding to the two first coils 41. The outer end wiring 51B is disposed outside the first coils 41. The outer end wiring 51B is disposed between the first coil 41 of transformer 40A and the first coil 41 of transformer 40B. The outer end wiring 51B is configured as a common terminal wiring for the first coils 41 of the transformers 40A and 40B. Alternatively, separate outer end wirings 51B may be provided for each of the first coils 41 of the transformers 40A and 40B.

As shown in FIGS. 8 and 9, the second conductor 52 is formed as a conductive layer embedded in one of the insulating layers 85 included in the insulating body 84. The second conductor 52 is embedded in an insulating layer 859 near the insulating upper surface 84S among the insulating layers 851 to 859 that form the insulating body 84. Therefore, the second conductor 52 is disposed closer to the insulating upper surface 84S than the first conductor 51 within the insulating body 84. The insulating layer 859 includes a groove 86B that penetrates both the thick insulating layer 85A and the thin insulating layer 85B in the Z direction. The second conductor 52 is embedded in the groove 86B of the insulating layer 859. The second conductor 52 and the insulating layer 859 are covered by the insulating layer 85U.

As shown in FIGS. 7 to 9, the second conductor 52 includes a second coil 42, an inner end wiring 52A, and an outer end wiring 52B. Each of the second coil 42, the inner end wiring 52A, and the outer end wiring 52B is formed of a material including one or more appropriately selected from Ti, TiN, Au, Ag, Cu, Al, and W. In one example, the second coil 42, the inner end wiring 52A, and the outer end wiring 52B are formed of the same material. In another example, the second coil 42, the inner end wiring 52A, and the outer end wiring 52B are formed of different materials. In one example, the first coil 41 and the second coil 42 are formed of the same material. In another example, the first coil 41 and the second coil 42 are formed of different materials.

As shown in FIG. 7, the second coil 42 has a spiral shape in plan view. In one example, the second coil 42 has an elliptical shape in plan view. In one example, the size and number of turns of the second coil 42 are the same as those of the first coil 41. Each of the second coils 42 of the transformers 40A and 40B includes a first end and a second end opposite the first end. The first end is the inner end of the second coil 42, and the second end is the outer end of the second coil 42. The first end of each of the second coils 42 of the transformers 40A and 40B is individually electrically connected to the corresponding inner end wiring 52A. The second end of each of the second coils 42 of the transformers 40A and 40B is electrically connected to the corresponding outer end wiring 52B.

The inner end wiring 52A is disposed inside each of the second coils 42 of the transformers 40A and 40B. In the first embodiment, two inner end wirings 52A are provided corresponding to the two second coils 42. The outer end wiring 52B is disposed outside the second coils 42. The outer end wiring 52B is disposed between the second coil 42 of transformer 40A and the second coil 42 of transformer 40B. The outer end wiring 52B is configured as a common terminal wiring for the second coils 42 of the transformers 40A and 40B. Alternatively, separate outer end wirings 52B may be provided for the second coils 42 of the transformers 40A and 40B.

As shown in FIG. 8, a plurality of insulating layers 85 are interposed between the first conductor 51 and the second conductor 52. In the insulating chip 80 of the first embodiment, five insulating layers 854 to 858 are interposed between the first conductor 51 and the second conductor 52. Accordingly, the insulating chip 80 of the first embodiment includes a first insulating body 841 including the insulating layer 853 in which the first conductor 51 is embedded; a second insulating body 842 including the insulating layer 859 in which the second conductor 52 is embedded; and a third insulating body 843 including the insulating layers 854 to 858 interposed in the Z direction between the first insulating body 841 and the second insulating body 842. It can be said that the first conductor 51 embedded in the first insulating body 841 is covered by the third insulating body 843. It can also be said that the second conductor 52 is provided on the third insulating body 843 that covers the first conductor 51. In the first embodiment, the first insulating body 841 includes the bottommost insulating layer 85L and insulating layers 851 to 853. The second insulating body 842 includes the insulating layer 859 and the topmost insulating layer 85U.

As shown in FIGS. 8 and 9, first electrode pads 81 are provided on the insulating upper surface 84S of the insulating body 84. As shown in FIG. 5, the first electrode pads 81 are disposed closer to the chip side surface 802 on the insulating upper surface 84S. The first electrode pads 81 are formed of a material including one or more appropriately selected from Cu, Al, Ni (nickel), Pd (palladium), and W.

As shown in FIGS. 5, 8, and 9, the first electrode pads 81 include first pads 81A and second pads 81B. The first electrode pads 81 include two first pads 81A electrically connected to the first coil 41 of transformer 40A, and two first pads 81A electrically connected to the first coil 41 of transformer 40B. The first electrode pads 81 also include two second pads 81B that are common to the first coils 41 of transformers 40A and 40B. The two first pads 81A are arranged side by side in the X direction. The two second pads 81B are arranged side by side in the X direction.

As shown in FIGS. 8 and 9, the first electrode pads 81 are electrically connected to the first conductor 51. More specifically, the insulating chip 80 includes a connection wiring 60 that connects the first conductor 51 and the first electrode pads 81. The connection wiring 60 is provided within the insulating body 84. The connection wiring 60 includes a first connection wiring 60A shown in FIG. 8 and a second connection wiring 60B shown in FIG. 9.

As shown in FIG. 8, the first pad 81A is electrically connected to the inner end wiring 51A of the first conductor 51 via the first connection wiring 60A. As shown in FIG. 9, the second pad 81B is electrically connected to the outer end wiring 51B of the first conductor 51 via the second connection wiring 60B. A detailed description of the first connection wiring 60A and the second connection wiring 60B will be provided later.

As shown in FIGS. 5, 8, and 9, second electrode pads 82 are provided on the insulating upper surface 84S of the insulating body 84. The second electrode pads 82 are formed of a material including one or more appropriately selected from Cu, Al, Ni, Pd, and W. In one example, the second electrode pads 82 are formed of the same material as the first electrode pads 81.

As shown in FIGS. 5 and 8, the second electrode pads 82 include third pads 82A and fourth pads 82B. The second electrode pads 82 include two third pads 82A electrically connected to the second coil 42 of transformer 40A, and two third pads 82A electrically connected to the second coil 42 of transformer 40B. The second electrode pads 82 also include two fourth pads 82B that are common to the second coils 42 of transformers 40A and 40B. The two third pads 82A are arranged side by side in the X direction. The two fourth pads 82B are arranged side by side in the X direction. The two third pads 82A are disposed inside the second coil 42 of the second conductor 52 in plan view. As shown in FIG. 8, the third pads 82A are arranged to overlap the inner end wiring 52A of the second conductor 52 in plan view. As shown in FIG. 5, the two fourth pads 82B are disposed outside the second coils 42 of transformers 40A and 40B in plan view. The two fourth pads 82B are disposed between the second coil 42 of transformer 40A and the second coil 42 of transformer 40B. As shown in FIG. 9, the two fourth pads 82B are arranged to overlap the outer end wiring 52B of the second conductor 52 in plan view.

As shown in FIGS. 8 and 9, the second electrode pads 82 are electrically connected to the second conductor 52. More specifically, the third pads 82A of the second electrode pads 82 are electrically connected to the inner end wiring 52A of the second conductor 52 via via wirings 56A that penetrate the topmost insulating layer 85U. As shown in FIG. 9, the fourth pads 82B of the second electrode pads 82 are electrically connected to the outer end wiring 52B of the second conductor 52 via via wirings 56B that penetrate the topmost insulating layer 85U. The via wirings 56A and 56B are formed of a material including one or more appropriately selected from Ti, TiN, Au, Ag, Cu, Al, and W.

The insulating chip 80 may include a passivation film 91. The passivation film 91 is a surface protection film for the insulating chip 80. The passivation film 91 is formed of a material including, for example, SiO₂ or SiN.

The first electrode pads 81 and the second electrode pads 82 are covered by the passivation film 91. The passivation film 91 includes openings that expose portions of the first electrode pads 81 and the second electrode pads 82. As a result, the first electrode pads 81 have exposed surfaces for connecting the wires W2 shown in FIG. 2. The second electrode pads 82 have exposed surfaces for connecting the wires W3 shown in FIG. 2.

The insulating chip 80 may include a resin layer 92 provided on the passivation film 91. The resin layer 92 may be formed of a material including, for example, PI (polyimide). The resin layer 92 is separated into an inner resin layer 921 and an outer resin layer 922 by a separation groove 923. As shown in FIG. 4, the separation groove 923 is provided so as to surround the transformers 40A and 40B. The resin layer 92 includes a first resin opening 924 that exposes the first electrode pads 81 and a second resin opening 925 that exposes the second electrode pads 82. The first resin opening 924 and the second resin opening 925 communicate with the openings of the passivation film 91.

As shown in FIGS. 5 and 7 to 9, the insulating chip 80 includes a dummy pattern 55 provided around the second coils 42 of the transformers 40A and 40B. The dummy pattern 55 may be omitted. As shown in FIGS. 8 and 9, the dummy pattern 55 is embedded in the insulating layer 859 of the insulating body 84, similarly to the second conductor 52.

As shown in FIGS. 5 and 7, the dummy pattern 55 includes a first dummy pattern 55A, a second dummy pattern 55B, and a third dummy pattern 55C. Each of the first dummy pattern 55A, the second dummy pattern 55B, and the third dummy pattern 55C is formed of a material including one or more appropriately selected from Ti, TiN, Au, Ag, Cu, Al, and W.

As shown in FIGS. 5 and 7, the first dummy pattern 55A is provided in a region between the second coil 42 of transformer 40A and the second coil 42 of transformer 40B in the X direction in plan view. The first dummy pattern 55A is formed with a pattern different from that of the second coils 42. The first dummy pattern 55A is electrically connected to the outer end wiring 52B. The first dummy pattern 55A may be electrically connected to at least one of the two outer end wirings 52B. Thus, the first dummy pattern 55A is at the same potential as the second coil 42. Therefore, the voltage of the first dummy pattern 55A may become higher than that of the first coil 41 in response to changes in the second reference potential of the second coil 42.

Although not shown in the drawings, the first dummy pattern 55A is disposed at the same position as the second coil 42 in the Z direction. In other words, the first dummy pattern 55A is located farther from the substrate 83 than the first coil 41. That is, the dummy pattern 55 is provided around the coil that is closer to the chip front surface 80S among the coils of transformers 40A and 40B in the insulating chip 80.

By making the first dummy pattern 55A have the same voltage as the second coil 42, voltage drop between the second coil 42 and the first dummy pattern 55A can be suppressed. Therefore, electric field concentration on the second coil 42 can be suppressed.

As shown in FIG. 7, the third dummy pattern 55C surrounds the second coils 42 of the transformers 40A and 40B in plan view. The third dummy pattern 55C is electrically connected to the first dummy pattern 55A. Therefore, similar to the first dummy pattern 55A, the voltage of the third dummy pattern 55C may become higher than that of the first coil 41 in response to changes in the second reference potential of the second coil 42.

As shown in FIG. 9, the third dummy pattern 55C is disposed at the same position as the second coil 42 in the Z direction. That is, the third dummy pattern 55C is located farther from the substrate 83 than the first coil 41. In this way, the dummy patterns 55A to 55C are all arranged at the same position in the Z direction.

By making the third dummy pattern 55C have the same voltage as the second coil 42, voltage drop between the second coil 42 and the third dummy pattern 55C can be suppressed. Therefore, electric field concentration on the second coil 42 can be suppressed.

As shown in FIG. 7, the second dummy pattern 55B surrounds the third dummy pattern 55C in plan view. The second dummy pattern 55B is independent from the second coil 42. In other words, the second dummy pattern 55B is not electrically connected to the second coil 42.

As shown in FIGS. 8 and 9, the second dummy pattern 55B is disposed at the same position as the second coil 42 in the Z direction. The second dummy pattern 55B is also disposed farther from the substrate 83 than the first coil 41. The second dummy pattern 55B suppresses an increase in the electric field intensity around the second coil 42 and also suppresses electric field concentration on the second electrode pads 82 (third pads 82A and fourth pads 82B).

As shown in FIGS. 6 to 9, the insulating chip 80 includes a sealing portion 93. The sealing portion 93 is provided on the outer peripheral region of the insulating body 84 in plan view. The sealing portion 93 has a rectangular frame shape in plan view. The sealing portion 93 surrounds the plurality of first electrode pads 81, the plurality of second electrode pads 82, the transformers 40A and 40B, and the first connection wiring 60A and second connection wiring 60B in plan view.

As shown in FIGS. 8 and 9, the sealing portion 93 extends in the Z direction within the insulating body 84 so as to surround the transformers 40A and 40B and the first connection wiring 60A and the second connection wiring 60B. The sealing portion 93 has the function of suppressing the intrusion of foreign matter such as moisture from the outside of the insulating chip 80. The sealing portion 93 is formed of a material including one or more appropriately selected from Ti, TiN, Au, Ag, Cu, Al, and W.

### <Structure of Connection Wiring>

As shown in FIG. 8, the first connection wiring 60A includes a first wiring portion 61A extending in the Z direction through a plurality of insulating layers 85, and a second wiring portion 66A extending in the Y direction.

The first wiring portion 61A is disposed at a position overlapping the first pad 81A in plan view. The first wiring portion 61A is connected to the first pad 81A. The first wiring portion 61A penetrates from the topmost insulating layer 85U to the insulating layer 853 near the bottommost insulating layer 85L among the plurality of insulating layers 85.

The first wiring portion 61A includes a first layer wiring 62A, a second layer wiring 63A, a through wiring 64A, and a surface-side via wiring 65A. Each of the first layer wiring 62A, the second layer wiring 63A, the through wiring 64A, and the surface-side via wiring 65A is formed of a material including one or more appropriately selected from Ti, TiN, Au, Ag, Cu, Al, and W. In one example, the first layer wiring 62A, the second layer wiring 63A, and the through wiring 64A may be formed of the same material. In another example, the first layer wiring 62A, the second layer wiring 63A, the through wiring 64A, and the surface-side via wiring 65A may be formed of different materials. In one example, the first layer wiring 62A may be formed of the same material as the first conductor 51. In one example, the second layer wiring 63A may be formed of the same material as the second conductor 52. In one example, the surface-side via wiring 65A may be formed of the same material as the via wirings 56A and 56B.

The first layer wiring 62A is disposed near the insulating lower surface 84R within the insulating body 84. In one example, the first layer wiring 62A is disposed at the same position as the first conductor 51 in the Z direction. The first layer wiring 62A is embedded in the insulating layer 853. More specifically, the first layer wiring 62A is embedded in a through hole 87A that penetrates the insulating layer 853 in the Z direction. The first layer wiring 62A is covered by the insulating layer 854.

The second layer wiring 63A is disposed near the insulating upper surface 84S within the insulating body 84. In one example, the second layer wiring 63A is disposed at the same position as the second conductor 52 in the Z direction. The second layer wiring 63A faces the first layer wiring 62A in the Z direction. The second layer wiring 63A is embedded in the insulating layer 859. More specifically, the second layer wiring 63A is embedded in a through hole 87B that penetrates the insulating layer 859 in the Z direction. The second layer wiring 63A is covered by the topmost insulating layer 85U.

The through wiring 64A connects the first layer wiring 62A and the second layer wiring 63A. In one example, the through wiring 64A penetrates five insulating layers 854 to 858 that are interposed between the first layer wiring 62A and the second layer wiring 63A. A plurality of through wirings 64A are provided spaced apart in the X and Y directions. The detailed structure of the through wiring 64A will be described later.

The surface-side via wiring 65A connects the second layer wiring 63A and the first electrode pad 81. More specifically, the first pad 81A of the first electrode pad 81 is electrically connected to the second layer wiring 63A via the surface-side via wiring 65A that penetrates the topmost insulating layer 85U. In one example, a plurality of surface-side via wirings 65A are provided spaced apart in the X and Y directions.

The second wiring portion 66A is electrically connected to the first conductor 51. The second wiring portion 66A extends outward beyond the first conductor 51 in plan view. In one example, the second wiring portion 66A extends toward the chip side surface 802 of the insulating chip 80 beyond the first conductor 51 in plan view.

The second wiring portion 66A includes a lead-out wiring 67A, a first back-side via wiring 68A, and a second back-side via wiring 69A. Each of the lead-out wiring 67A, the first back-side via wiring 68A, and the second back-side via wiring 69A is formed of a material including one or more appropriately selected from Ti, TiN, Au, Ag, Cu, Al, and W. In one example, the lead-out wiring 67A, the first back-side via wiring 68A, and the second back-side via wiring 69A may be formed of the same material. In another example, they may be formed of different materials. In one example, the lead-out wiring 67A may be formed of the same material as the first conductor 51. In one example, the lead-out wiring 67A may be formed of the same material as the second conductor 52.

The lead-out wiring 67A is provided closer to the substrate 83 in the Z direction than the first wiring portion 61A. The lead-out wiring 67A is provided closer to the substrate 83 in the Z direction than the first conductor 51. In one example, the lead-out wiring 67A is provided in the insulating layer 851, which is one layer above the bottommost insulating layer 85L among the plurality of insulating layers 85. Among both end portions in the X direction, the first end portion of the lead-out wiring 67A, which is closer to the chip side surface 802 of the insulating chip 80, is provided at a position overlapping the first wiring portion 61A in plan view. The first end portion of the lead-out wiring 67A is connected to the first layer wiring 62A by a plurality of first back-side via wirings 68A. The second end portion of the lead-out wiring 67A, opposite the first end portion, is provided at a position overlapping the inner end wiring 51A of the first conductor 51 in plan view. The second end portion of the lead-out wiring 67A is connected to the inner end wiring 51A by a plurality of second back-side via wirings 69A.

As shown in FIG. 9, the second connection wiring 60B includes a first wiring portion 61B and a second wiring portion 66B, similar to the first connection wiring 60A shown in FIG. 8.

The first wiring portion 61B, like the first wiring portion 61A of the first connection wiring 60A, includes a first layer wiring 62B, a second layer wiring 63B, a through wiring 64B, and a surface-side via wiring 65B. Each of the first layer wiring 62B, the second layer wiring 63B, the through wiring 64B, and the surface-side via wiring 65B is formed of a material including one or more appropriately selected from Ti, TiN, Au, Ag, Cu, Al, and W. In one example, the first layer wiring 62B, the second layer wiring 63B, the through wiring 64B, and the surface-side via wiring 65B are formed of the same materials as the first layer wiring 62A, the second layer wiring 63A, the through wiring 64A, and the surface-side via wiring 65A shown in FIG. 8.

The first layer wiring 62B is provided at the same position in the Z direction as the first layer wiring 62A. The second layer wiring 63B is provided at the same position in the Z direction as the second layer wiring 63A. The structures of the first layer wiring 62B, the second layer wiring 63B, the through wiring 64B, and the surface-side via wiring 65B are the same as those of the first layer wiring 62A, the second layer wiring 63A, the through wiring 64A, and the surface-side via wiring 65A.

The second wiring portion 66B connects the outer end wiring 51B of the first conductor 51 and the first layer wiring 62B. The second wiring portion 66B extends outward beyond the first conductor 51 in plan view. Similar to the second wiring portion 66A shown in FIG. 8, the second wiring portion 66B includes a lead-out wiring 67B, a first back-side via wiring 68B, and a second back-side via wiring 69B. Each of the lead-out wiring 67B, the first back-side via wiring 68B, and the second back-side via wiring 69B is formed of a material including one or more appropriately selected from Ti, TiN, Au, Ag, Cu, Al, and W. In one example, they are formed of the same materials as the lead-out wiring 67A, the first back-side via wiring 68A, and the second back-side via wiring 69A shown in FIG. 8.

The lead-out wiring 67B is provided at the same position in the Z direction as the lead-out wiring 67A. The first end of the lead-out wiring 67B is provided at a position overlapping the second pad 81B of the first electrode pad 81 in plan view. The first end of the lead-out wiring 67B is connected to the first layer wiring 62B by the first back-side via wiring 68B. The second end of the lead-out wiring 67B is provided at a position overlapping the outer end wiring 51B of the first conductor 51 in plan view. The second end of the lead-out wiring 67B is connected to the outer end wiring 51B by the second back-side via wiring 69B. The structures of the first back-side via wiring 68B and the second back-side via wiring 69B are the same as those of the first back-side via wiring 68A and the second back-side via wiring 69A.

The second wiring portion 66B includes a third back-side via wiring 69C that connects the lead-out wiring 67B and the substrate 83. Accordingly, the second connection wiring 60B is electrically connected to the substrate 83. The third back-side via wiring 69C penetrates the bottommost insulating layer 85L. The third back-side via wiring 69C is formed of a material including one or more appropriately selected from Ti, TiN, Au, Ag, Cu, Al, and W.

### <Structure of the Through Wiring>

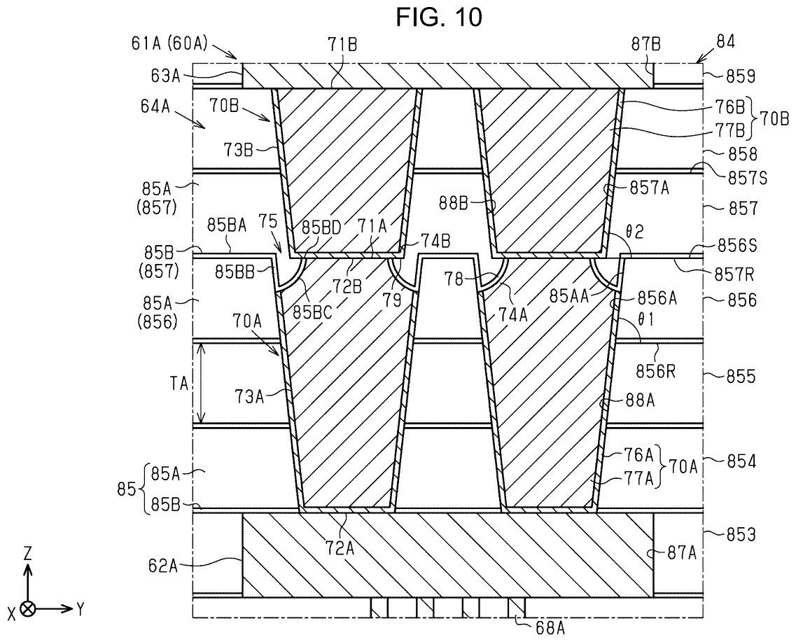

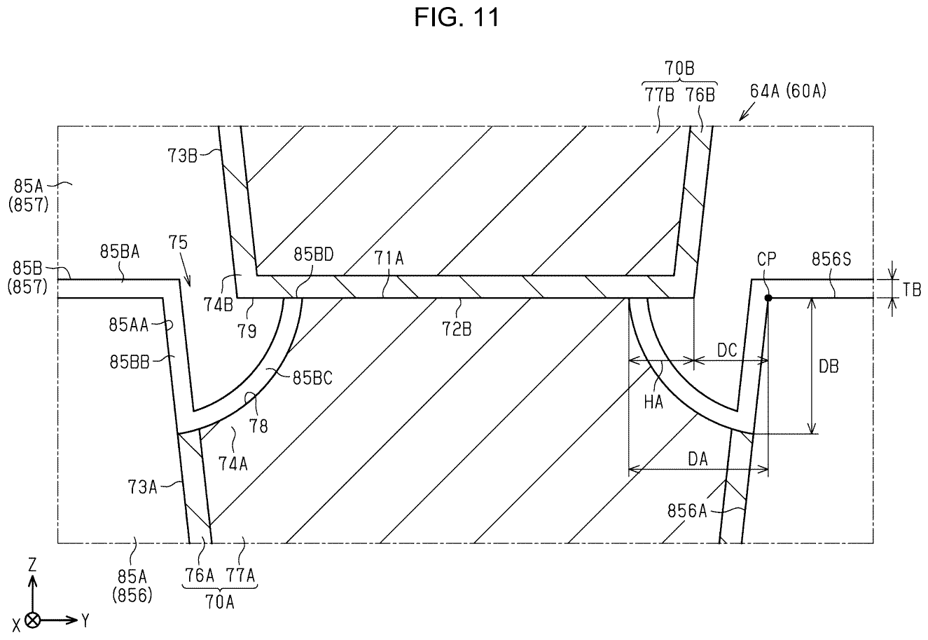

Referring to FIGS. 10 and 11, the detailed structure of the through wiring 64A is described. FIG. 10 schematically shows an enlarged cross-sectional structure of the through wiring 64A in FIG. 8 and its surroundings. FIG. 11 schematically shows an enlarged cross-sectional structure of a part of the through wiring 64A in FIG. 10.

Since the through wiring 64B of the second connection wiring 60B has the same structure as the through wiring 64A of the first connection wiring 60A, description thereof is omitted.

As shown in FIG. 10, a plurality of through wirings 64A are provided. The plurality of through wirings 64A are arranged spaced apart in a direction orthogonal to the Z direction. Each of the through wirings 64A includes a first via 70A and a second via 70B provided on the first via 70A. More specifically, the insulating body 84 is provided with a first through hole 88A corresponding to the first via 70A and a second through hole 88B corresponding to the second via 70B. The first through hole 88A and the second through hole 88B communicate with each other. The first via 70A is embedded in the first through hole 88A. The second via 70B is embedded in the second through hole 88B.

The first through hole 88A penetrates the plurality of thick insulating layers 85A and the plurality of thin insulating layers 85B. Therefore, the first via 70A embedded in the first through hole 88A penetrates the plurality of thick insulating layers 85A and the plurality of thin insulating layers 85B.

In the first embodiment, the first through hole 88A penetrates three insulating layers 85. Specifically, the first through hole 88A penetrates the insulating layers 854 to 856. Thus, the first through hole 88A exposes the first layer wiring 62A provided in the insulating layer 853. As a result, the first via 70A embedded in the first through hole 88A penetrates the insulating layers 854 to 856 and is in contact with the first layer wiring 62A.

The insulating layer 856 includes a side surface 856A that constitutes a side surface of the first through hole 88A. The side surface 856A is inclined such that the opening area of the first through hole 88A in plan view decreases from the upper surface 856S of the insulating layer 856 toward the lower surface 856R. The angle θ₁ of the side surface 856A is 70° or more and 90° or less. In one example, the angle θ₁ is 80°. Here, the angle θ₁ can be defined as the angle between the lower surface 856R of the insulating layer 856 and the side surface 856A. It should be noted that, as indicated by the range of angle θ₁, the side surface 856A may be a surface along the Z direction. That is, the side surface 856A may not be inclined.

The first via 70A is circular in plan view. In the first embodiment, the first via 70A has a truncated cone shape. The first via 70A includes a first via upper surface 71A, a first via lower surface 72A, and a first via side surface 73A.

The first via upper surface 71A is disposed closer to the insulating upper surface 84S (see FIG. 9) of the insulating body 84 in the Z direction. In one example, the first via upper surface 71A is circular in plan view. The first via lower surface 72A is a surface opposite to the first via upper surface 71A in the Z direction. In one example, the first via lower surface 72A is circular in plan view. The first via lower surface 72A is in contact with the first layer wiring 62A. The first via side surface 73A is provided between the first via upper surface 71A and the first via lower surface 72A in the Z direction. The first via side surface 73A is tapered so as to narrow from the first via upper surface 71A toward the first via lower surface 72A. Note that, when the side surface 856A is a surface along the Z direction, the first via 70A has a cylindrical shape. In that case, the first via side surface 73A becomes a surface along the Z direction.

In the first embodiment, the first via upper surface 71A is disposed at the same position in the Z direction as the upper surface 856S of the insulating layer 856. Here, the upper surface 856S of the insulating layer 856 is constituted by the upper surface of the thick insulating layer 85A in the insulating layer 856. The upper surface 856S of the insulating layer 856 may also be regarded as the boundary between the thick insulating layer 85A of the insulating layer 856 and the thin insulating layer 85B of the insulating layer 857. Note that the position of the first via upper surface 71A in the Z direction can be arbitrarily changed. In one example, the first via upper surface 71A may be disposed closer to the lower surface 856R of the insulating layer 856 than to the upper surface 856S of the insulating layer 856 in the Z direction.

The first via side surface 73A is in contact with the insulating layers 854 to 856. More specifically, the first via side surface 73A is in contact with both the thick insulating layer 85A and the thin insulating layer 85B in the insulating layers 854 and 855. The first via side surface 73A is in contact with the thick insulating layer 85A in the insulating layer 856, but is not in contact with the thin insulating layer 85B in the insulating layer 856. In one example, the thickness of the insulating layer 856 is smaller than the thicknesses of each of the insulating layers 855 and 854. The first via side surface 73A is provided along the side surface 856A (the side surface constituting the first through hole 88A) of the insulating layer 856. Here, the insulating layer 856 is an example of the “first insulating layer.” The insulating layer 857 laminated on the first insulating layer 856 is an example of the “second insulating layer.”

The first via 70A includes a seed layer 76A and a plating layer 77A provided on the seed layer 76A. The seed layer 76A is provided on the side surface of the first through hole 88A (i.e., the side surface 856A of the insulating layer 856) and on the upper surface of the first layer wiring 62A exposed through the first through hole 88A. Therefore, both the first via lower surface 72A and the first via side surface 73A are formed of the seed layer 76A. The first via upper surface 71A is formed of the plating layer 77A. The seed layer 76A is, for example, a sputtered film formed by sputtering. The seed layer 76A may have a laminated structure including, for example, a Ti film and a Cu film. The plating layer 77A is formed of a material including Cu, for example.

The first via 70A includes a first corner portion 74A provided between the first via upper surface 71A and the first via side surface 73A. A recess 75 is provided in the first corner portion 74A. The first via upper surface 71A and the first via side surface 73A are connected via the recess 75. The recess 75 is provided around the entire periphery of the first via 70A in plan view. Therefore, the recess 75 is annular in plan view. The recess 75 is provided across both the seed layer 76A and the plating layer 77A.

Because the recess 75 is provided in the first via 70A, the first via upper surface 71A becomes smaller than the first via lower surface 72A. In other words, the area of the first via upper surface 71A is smaller than that of the first via lower surface 72A. In the first embodiment, the diameter of the first via upper surface 71A is smaller than that of the first via lower surface 72A.

As shown in FIG. 11, the recess 75 includes a curved surface 78 recessed in a manner convex inward toward the first via 70A. In the sectional view of FIG. 11, the curved surface 78 is arcuate centered on a curvature center CP. The curvature center CP is located outside the first via 70A. In one example, the curvature center CP is at the same position in the Z direction as the first via upper surface 71A. In one example, the curvature center CP may be defined as the intersection of a first virtual line along the side surface 856A of the insulating layer 856 and a second virtual line along the upper surface 856S of the insulating layer 856. Since the first via side surface 73A is inclined with respect to the Z direction, the distance DA between the curvature center CP and the first via upper surface 71A is slightly greater than the distance DB between the curvature center CP and the first via side surface 73A in the Z direction. The distance DA is the radius of curvature from the curvature center CP to the curved surface 78. The distances DA and DB are smaller than the thickness TA of the thick insulating layer 85A (see FIG. 10). The distances DA and DB are greater than the thickness TB of the thin insulating layer 85B. The distances DA and DB are greater than twice the thickness TB of the thin insulating layer 85B. In one example, the distances DA and DB are equal to or less than the radius of the first via upper surface 71A. In one example, the distances DA and DB are 1 μm. Note that the distances DA and DB can be arbitrarily changed.

As shown in FIG. 10, the second through hole 88B penetrates the plurality of thick insulating layers 85A and the plurality of thin insulating layers 85B. In the first embodiment, the second through hole 88B penetrates two insulating layers 85. Specifically, the second through hole 88B penetrates the insulating layers 857 and 858. Thus, the second through hole 88B exposes the first via upper surface 71A. As a result, the second via 70B embedded in the second through hole 88B penetrates the insulating layers 857 and 858 and is in contact with the first via upper surface 71A.

The insulating layer 857 includes a side surface 857A that forms the second through hole 88B. The side surface 857A is inclined such that the opening area of the second through hole 88B in plan view decreases from the upper surface 857S of the insulating layer 857 toward the lower surface 857R. The angle θ2 of the side surface 857A is 70° or more and 90° or less. In one example, the angle θ2 is 80°. Here, the angle θ2 can be defined as the angle between the lower surface 857R of the insulating layer 857 and the side surface 857A. Note that, as with the range of angle θ2, the side surface 857A may be a surface along the Z direction. That is, the side surface 857A may not be inclined.

The second via 70B embedded in the second through hole 88B penetrates the insulating layers 857 and 858. Therefore, the dimension of the second via 70B in the Z direction is smaller than that of the first via 70A, which penetrates the insulating layers 854 to 856.

The second via 70B is circular in plan view. In the first embodiment, the second via 70B is in the shape of a truncated cone. The second via 70B includes a second via upper surface 71B, a second via lower surface 72B, and a second via side surface 73B.

The second via upper surface 71B is disposed near the insulating upper surface 84S of the insulating body 84. The second via upper surface 71B is in contact with the lower surface of the second layer wiring 63A. In one example, the second via upper surface 71B is circular in plan view. The second via lower surface 72B is a surface on the side opposite to the second via upper surface 71B in the Z direction. In one example, the second via lower surface 72B is circular in plan view. The second via lower surface 72B is smaller than the second via upper surface 71B. That is, the area of the second via lower surface 72B is smaller than the area of the second via upper surface 71B. It can also be said that the diameter of the second via lower surface 72B is smaller than that of the second via upper surface 71B. The second via side surface 73B is provided between the second via upper surface 71B and the second via lower surface 72B in the Z direction. The second via side surface 73B is tapered, narrowing from the second via upper surface 71B toward the second via lower surface 72B. If the side surface 857A is a surface along the Z direction, the second via 70B has a cylindrical shape. In this case, the second via side surface 73B becomes a surface along the Z direction.

The second via lower surface 72B is in contact with the first via upper surface 71A of the first via 70A. In the first embodiment, the second via lower surface 72B is disposed at the same position as the upper surface 856S of the insulating layer 856 in the Z direction. Note that the position of the second via lower surface 72B in the Z direction can be arbitrarily changed according to the position of the first via upper surface 71A. In one example, the second via lower surface 72B may be disposed closer to the lower surface 856R of the insulating layer 856 than the upper surface 856S in the Z direction.

The second via lower surface 72B is larger than the first via upper surface 71A. That is, the area of the second via lower surface 72B is larger than that of the first via upper surface 71A. It can be said that the diameter of the second via lower surface 72B is larger than that of the first via upper surface 71A. Therefore, the second via lower surface 72B includes an extension portion 79 that protrudes beyond the first via upper surface 71A in plan view. In one example, the extension portion 79 is annular in plan view. That is, the extension portion 79 is provided so as to surround the entire circumference of the first via upper surface 71A in plan view.

As shown in FIG. 11, the protrusion length HA of the extension portion 79 is smaller than the distance DC between the side surface 856A of the insulating layer 856 and the second via lower surface 72B in plan view at the same Z-direction position as the upper surface 856S of the insulating layer 856. Further, the protrusion length HA of the extension portion 79 is smaller than the distance DA between the curvature center CP of the recess 75 of the first via 70A and the first via upper surface 71A. Furthermore, the protrusion length HA is smaller than the distance DB between the curvature center CP of the recess 75 of the first via 70A and the first via side surface 73A in the Z direction. In one example, the protrusion length HA of the extension portion 79 is greater than the thickness TB of the thin insulating layer 85B of the insulating layer 857. In one example, the protrusion length HA is smaller than the thickness TA of the thick insulating layer 85A of the insulating layer 856. Here, the protrusion length HA of the extension portion 79 can be defined, for example, as one-half the difference between the diameters of the second via lower surface 72B and the first via upper surface 71A.

As shown in FIG. 10, the second via side surface 73B is in contact with the insulating layers 857 and 858. More specifically, the second via side surface 73B is in contact with both the thick insulating layer 85A and the thin insulating layer 85B of the insulating layer 858. The second via side surface 73B is in contact with the thick insulating layer 85A of the insulating layer 857, but not with the thin insulating layer 85B of the insulating layer 857.

The second via 70B includes a seed layer 76B and a plating layer 77B formed on the seed layer 76B. The seed layer 76B is provided on the side surface forming the second through hole 88B and on the upper surface of the first via upper surface 71A exposed by the second through hole 88B. Accordingly, both the second via lower surface 72B and the second via side surface 73B are formed of the seed layer 76B. The second via upper surface 71B is formed of the plating layer 77B. The seed layer 76B is, for example, a sputtered film formed by sputtering. The seed layer 76B may have a laminated structure of a Ti film and a Cu film, for example. The plating layer 77B is formed of a material containing, for example, Cu.

The second via 70B includes a second corner portion 74B formed by the second via lower surface 72B and the second via side surface 73B. The second corner portion 74B includes the extension portion 79. The second via lower surface 72B is disposed at the same position as the upper surface 856S of the insulating layer 856 in the Z direction. Therefore, the second corner portion 74B includes a portion positioned closer to the insulating layer 857 than the upper surface 856S of the insulating layer 856 in the Z direction.

As shown in FIG. 11, the thick insulating layer 85A of the insulating layer 856 includes an exposed side surface 85AA exposed by the recess 75 from the first via side surface 73A. The exposed side surface 85AA is a portion between the upper end edge of the first via side surface 73A and the upper surface 856S of the insulating layer 856, on the side surface 856A of the insulating layer 856. The exposed side surface 85AA faces the curved surface 78 of the recess 75 in a direction perpendicular to the Z direction. In one example, the length of the exposed side surface 85AA is equal to the radius of curvature of the curved surface 78. Here, the length of the exposed side surface 85AA can be defined as the distance between the upper end edge of the first via side surface 73A and the upper surface 856S of the insulating layer 856.

The thin insulating layer 85B of the insulating layer 857 includes an upper surface portion 85BA, a side surface portion 85BB, and a curved portion 85BC. The upper surface portion 85BA, the side surface portion 85BB, and the curved portion 85BC are integrated.

The upper surface portion 85BA is laminated on the upper surface 856S of the insulating layer 856. The upper surface portion 85BA faces the second corner portion 74B of the second via 70B in a direction perpendicular to the Z direction. In one example, the upper surface portion 85BA is disposed so as to surround the second corner portion 74B in plan view. The upper surface portion 85BA is disposed to be spaced apart from the second corner portion 74B in a direction perpendicular to the Z direction.

The side surface portion 85BB is provided along the exposed side surface 85AA. The side surface portion 85BB includes a first portion facing the second corner portion 74B of the second via 70B in a direction perpendicular to the Z direction. The side surface portion 85BB includes a second portion that is closer to the lower surface 856R of the insulating layer 856 (see FIG. 10) than the second via 70B in the Z direction. The second portion is provided inside the recess 75 in a direction perpendicular to the Z direction.

The curved portion 85BC is provided along the curved surface 78 of the recess 75. The curved portion 85BC is provided within the recess 75. The curved portion 85BC is in contact with an inner portion of the second via lower surface 72B, closer to the inside than the second via side surface 73B. An end surface 85BD of the curved portion 85BC is in contact with a portion spaced apart from the outer edge of the second via lower surface 72B.

The thick insulating layer 85A of the insulating layer 857 is embedded in the recess 75. More specifically, the thick insulating layer 85A of the insulating layer 857 is embedded in a recessed space formed by the side surface portion 85BB and the curved portion 85BC of the thin insulating layer 85B of the insulating layer 857. Therefore, the thick insulating layer 85A of the insulating layer 857 is interposed between the upper surface portion 85BA of the thin insulating layer 85B of the insulating layer 857 and the second corner portion 74B of the second via 70B. Thus, the recess 75 may be said to be filled with the insulating layer 857.

The thick insulating layer 85A of the insulating layer 857 is in contact with the second corner portion 74B of the second via 70B. The thick insulating layer 85A of the insulating layer 857 may be said to cover the second corner portion 74B. More specifically, the thick insulating layer 85A of the insulating layer 857 is in contact with the second via side surface 73B and the second via lower surface 72B, which form the second corner portion 74B. The thick insulating layer 85A of the insulating layer 857 may be said to be in contact with the outer edge of the second via lower surface 72B and the second via side surface 73B extending continuously from the outer edge. The thick insulating layer 85A of the insulating layer 857 is in contact with a portion of the second via lower surface 72B from the outer edge to the point where the end surface 85BD of the thin insulating layer 85B of the insulating layer 857 is in contact. Therefore, the thick insulating layer 85A of the insulating layer 857 may be said to be in contact with the end of the extension portion 79. Here, the end of the extension portion 79 refers to the portion of the extension portion 79 that includes the outer peripheral edge of the second via lower surface 72B and is located closer to the periphery than the point where the curved portion 85BC of the thin insulating layer 85B of the insulating layer 857 is in contact. Thus, the extension portion 79 is in contact with both the thick insulating layer 85A and the thin insulating layer 85B of the insulating layer 857.

### <Manufacturing Method of the Insulating Chip>

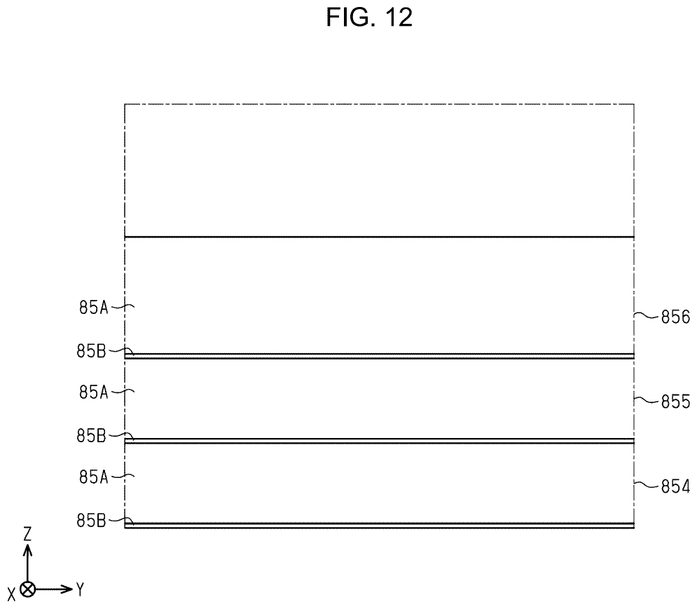

With reference to FIGS. 12 to 20, an example of a method for manufacturing the insulating chip 80 will be described. FIGS. 12 to 20 are schematic cross-sectional views showing an example manufacturing method for the through wiring 64A of the first connection wiring 60A of the insulating chip 80. Note that FIGS. 12 to 20 illustrate a portion of the insulating chip 80 shown in FIG. 8, and schematically show the cross-sectional structure of the through wiring 64A shown in FIG. 10. Therefore, in FIGS. 12 to 20, components other than the insulating layers 85 around the through wiring 64A are omitted. For component references not shown in the figures, refer to FIGS. 8 to 11. Also, in FIGS. 12 to 20, for ease of understanding, components that form the final structure of the insulating chip 80 or components corresponding thereto may be partially denoted with reference numerals from FIGS. 8 to 11 in parentheses.

As shown in FIG. 12, the manufacturing method of the insulating chip 80 includes a step of forming the insulating layers 854 to 856. In one example, the insulating layers 854 to 856 are formed on the insulating layer 853 by chemical vapor deposition (CVD). In one example, the lowermost insulating layer 85L is first formed on the upper surface 83S of the substrate 83. Subsequently, the insulating layers 851 to 856 are formed by repeatedly laminating the thick insulating layers 85A and the thin insulating layers 85B. Thus, the insulating layers 854 to 856 are formed on the insulating layer 853.

As shown in FIG. 12, the thickness of the insulating layer 856 is greater than the thickness of the insulating layers 854 and 855. More specifically, the thickness of the thick insulating layer 85A of the insulating layer 856 is greater than the thicknesses of the thick insulating layers 85A of the insulating layers 854 and 855. The thickness of the thin insulating layer 85B of the insulating layer 856 is equal to the thicknesses of the thin insulating layers 85B of the insulating layers 854 and 855.

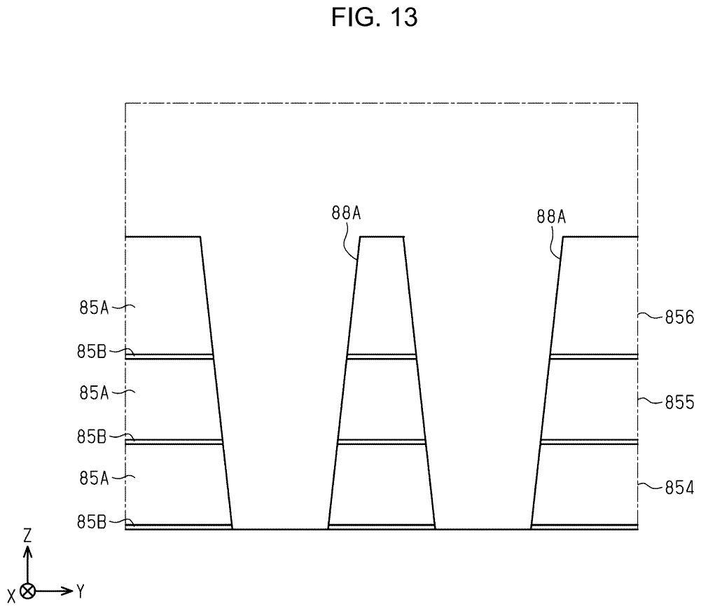

As shown in FIG. 13, the method for manufacturing the insulating chip 80 includes a step of forming the first through hole 88A. In one example, the first through hole 88A is formed in the insulating layers 854 to 856 by collectively etching the insulating layers 854 to 856 in a selective manner to expose a part of the upper surface of the first layer wiring 62A (see FIG. 8).

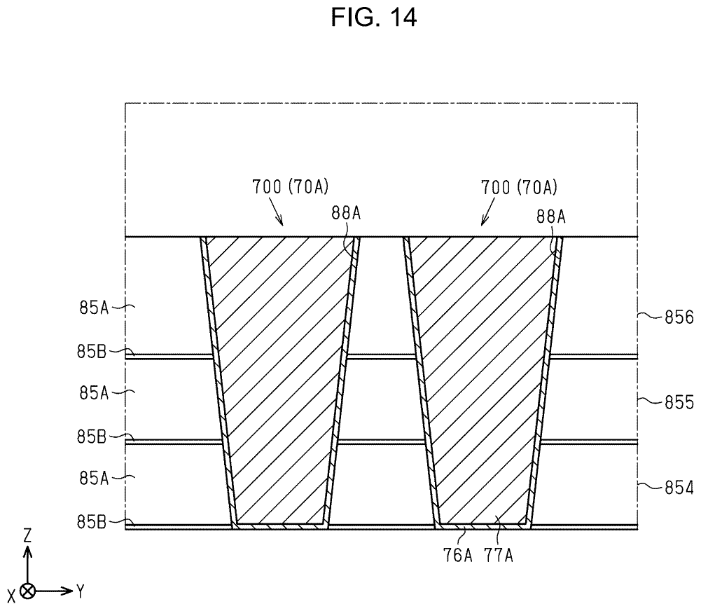

As shown in FIGS. 14 to 17, the method for manufacturing the insulating chip 80 includes a step of forming the first via 70A.

As shown in FIG. 14, the step of forming the first via 70A includes a step of forming the conductive layer 700. In this step, the conductive layer 700 is formed on the side surface of the first through hole 88A and on the upper surface of the first layer wiring 62A exposed by the first through hole 88A, for example, by electroplating. The conductive layer 700 may include the seed layer 76A and the plating layer 77A. In one example, a seed layer 76A covering the side surface of the first through hole 88A and the upper surface of the first layer wiring 62A exposed by the first through hole 88A is formed by sputtering. Subsequently, a conductive layer 700 is formed by plating growth from the seed layer 76A using, for example, a conductive material containing Cu. The conductive layer 700 is formed so as to fill the first through hole 88A that penetrates collectively through the insulating layers 854 to 856.

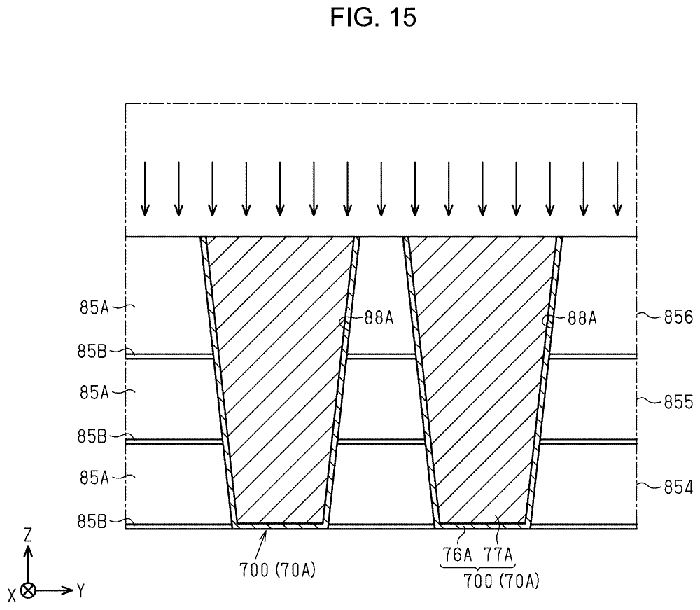

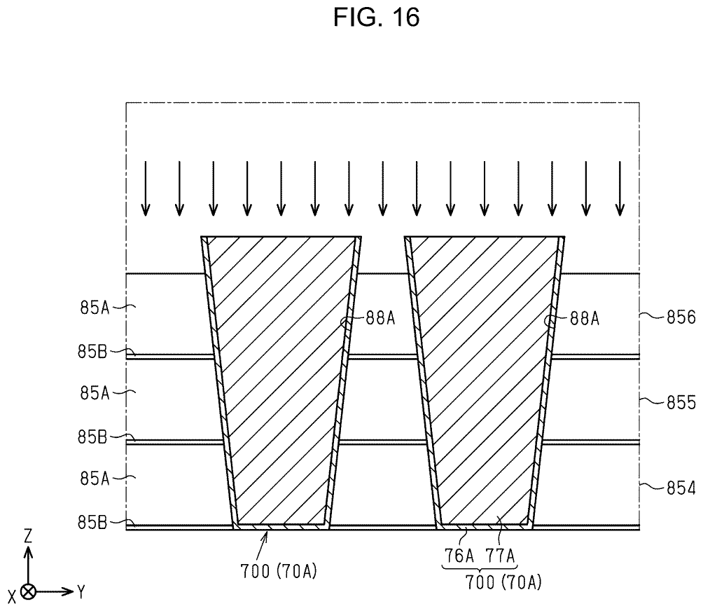

As shown in FIG. 15, the step of forming the first via 70A includes a step of thinning the insulating layer 856. In this step, for example, the thick insulating layer 85A of the insulating layer 856 is partially removed by dry etching such that the thickness of the thick insulating layer 85A becomes smaller. As a result, as shown in FIG. 16, the conductive layer 700 protrudes from the thick insulating layer 85A of the insulating layer 856. The thickness of the insulating layer 856 after thinning is, for example, equal to the thickness of the insulating layer 855.

Subsequently, as shown in FIG. 16, the step of forming the first via 70A includes a step of partially removing the conductive layer 700. In this step, for example, the portion of the conductive layer 700 protruding from the thick insulating layer 85A of the insulating layer 856 is removed by wet etching (isotropic etching).

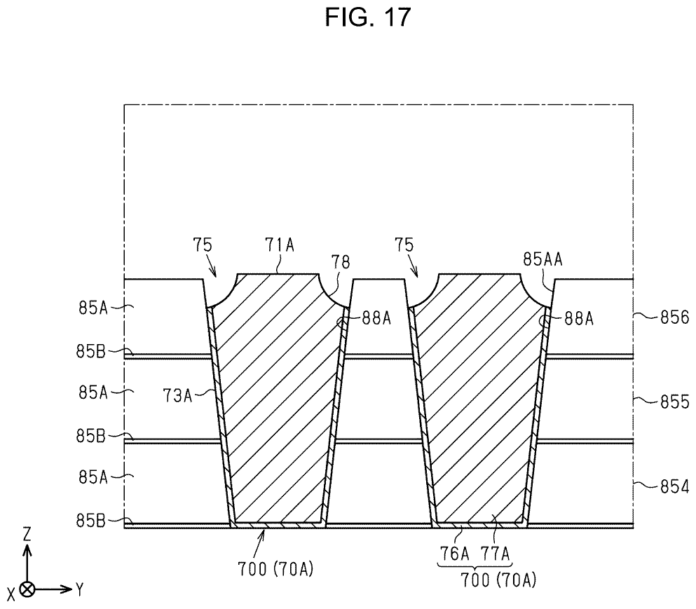

Next, as shown in FIG. 17, the step of forming the first via 70A includes a step of forming the recess 75. In this step, for example, the recess 75 is formed by wet etching (isotropic etching). By forming the recess 75, the first via upper surface 71A and the first via side surface 73A are formed. Through the above steps, the first via 70A is formed. In addition, the recess 75 causes the exposed side surface 85AA to be formed in the insulating layer 856.

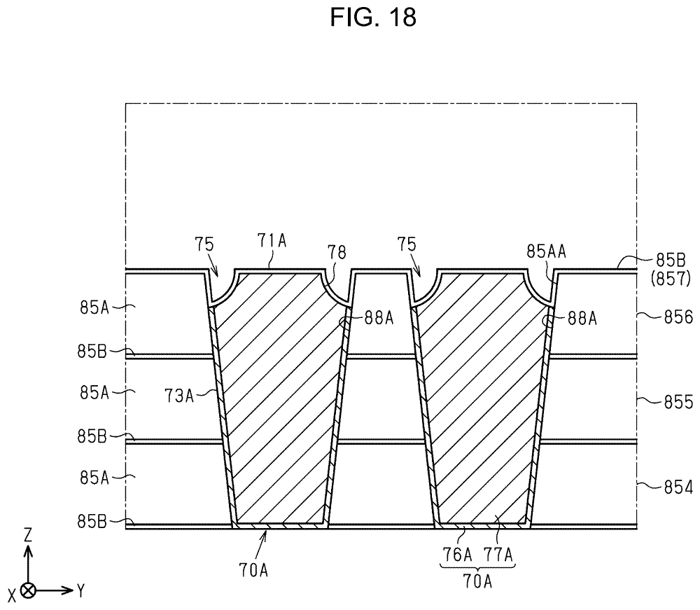

As shown in FIG. 18, the method for manufacturing the insulating chip 80 includes a step of forming the thin insulating layer 85B. In this step, the thin insulating layer 85B is formed so as to cover the upper surface of the thick insulating layer 85A of the insulating layer 856, the exposed side surface 85AA, the curved surface 78 of the recess 75, and the first via upper surface 71A. The thin insulating layer 85B formed in this step is the thin insulating layer 85B of the insulating layer 857.

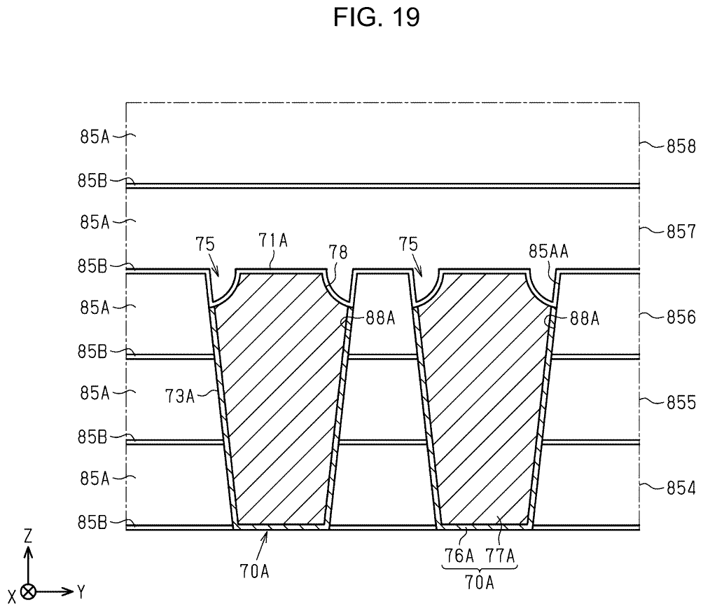

As shown in FIG. 19, the method for manufacturing the insulating chip 80 includes a step of forming the insulating layers 857 and 858. In this step, the insulating layers 857 and 858 are formed by alternately laminating the thick insulating layer 85A and the thin insulating layer 85B, for example by a CVD method. In the step of forming the insulating layer 857, the thick insulating layer 85A of the insulating layer 857 is formed so as to be embedded in the recess 75.

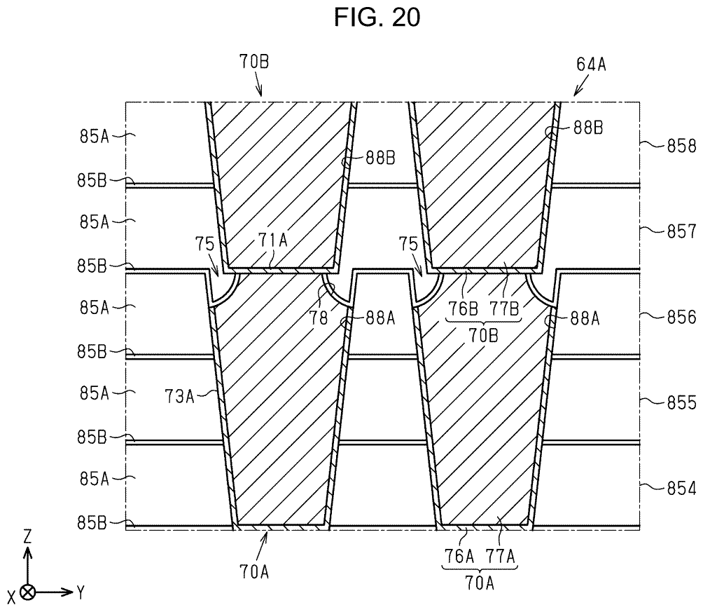

As shown in FIG. 20, the method for manufacturing the insulating chip 80 includes a step of forming the second through hole 88B and a step of forming the second via 70B.

In the step of forming the second through hole 88B, for example, the second through hole 88B is formed in the insulating layers 857 and 858 by collectively and selectively etching the insulating layers 857 and 858 so as to expose the upper surface 71A of the first via 70A. As the etching method, for example, reactive ion etching is used. In this step, the portion of the thin insulating layer 85B of the insulating layer 856 that covers the upper surface 71A of the first via 70A is removed by the etching. The second through hole 88B exposes the entire upper surface 71A of the first via 70A. In this step, a part of the thick insulating layer 85A of the insulating layer 857 embedded in the recess 75 is also removed.

In the step of forming the second via 70B, the second via 70B is formed on the upper surface 71A of the first via 70A exposed through the second through hole 88B, for example by electroplating. In one example, a seed layer 76B covering the side surface of the second through hole 88B and the upper surface 71A of the first via 70A exposed by the second through hole 88B is formed by sputtering. Then, the second via 70B is formed by plating growth from the seed layer 76B using a conductive material containing Cu, for example. The second via 70B is formed so as to fill the second through hole 88B that collectively penetrates the insulating layers 857 and 858. Through these steps, the through wiring 64A is formed.

### [Operation of First Embodiment]

The operation of the first embodiment is described below.

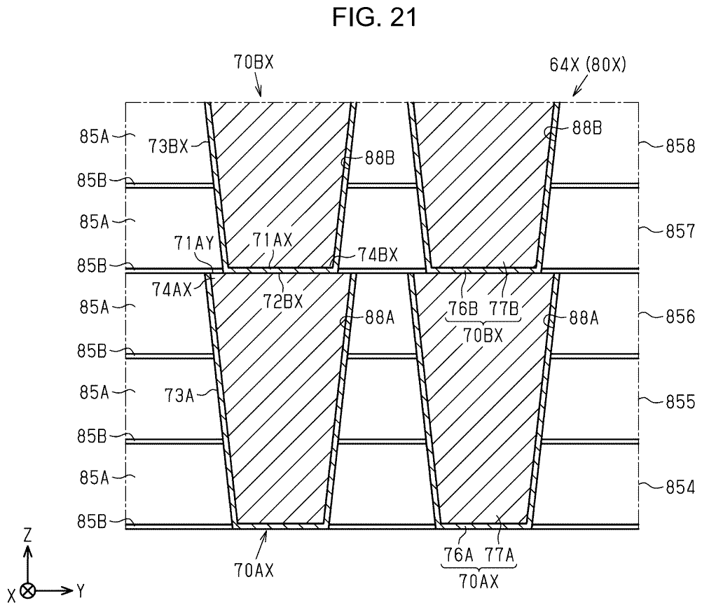

FIG. 21 schematically shows a cross-sectional structure of a through wiring 64X of a comparative insulating chip 80X.

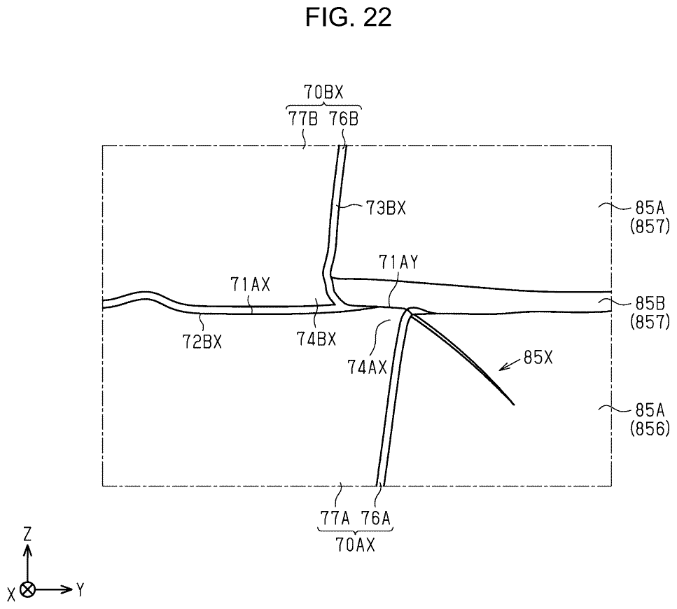

FIG. 22 schematically shows an enlarged cross-sectional structure of the joint portion between the first via 70AX and the second via 70BX and the surrounding area of the through wiring 64X shown in FIG. 21.

As shown in FIG. 21, in the through wiring 64X of the comparative insulating chip 80X, the first via 70AX does not include the recess 75 as shown in FIG. 11. Therefore, the upper surface 71AX of the first via 70AX is larger than the lower surface 72BX of the second via 70BX. That is, the upper surface 71AX of the first via includes an exposed portion 71AY that protrudes from the lower surface 72BX of the second via. A thin insulating layer 85B of the insulating layer 856 is laminated on this exposed portion 71AY. The thin insulating layer 85B of the insulating layer 857 is in contact with the side surface 73BX of the second via 70BX, which forms the second corner portion 74BX of the second via 70BX.

In the comparative insulating chip 80X, when heat is applied to the insulating chip 80X due to changes in the external environmental temperature, thermal expansion of the first corner portion 74AX of the first via 70AX and thermal expansion of the second corner portion 74BX of the second via 70BX cause stress to concentrate on the exposed portion 71AY forming the first corner portion 74AX of the first via 70AX. In particular, since the thermal expansion coefficient of the thin insulating layer 85B is greater than that of the thick insulating layer 85A, stress is likely to concentrate between the thin insulating layer 85B and the exposed portion 71AY. As this stress increases, a force that peels the thin insulating layer 85B from the thick insulating layer 85A is applied to the exposed portion 71AY. As a result, if the thin insulating layer 85B peels from the thick insulating layer 85A, a crack 85X may form in the thick insulating layer 85A of the insulating layer 856, as shown in FIG. 22. This raises concerns about the reduction of the withstand voltage of the insulating chip 80.

In this respect, in the insulating chip 80 of the first embodiment, as shown in FIG. 11, the lower surface 72B of the second via 70B in the through wiring 64A includes an extension portion 79 that protrudes beyond the upper surface 71A of the first via 70A due to the recess 75 of the first via 70A. The extension portion 79 is in contact with the thick insulating layer 85A. Thus, unlike the comparative insulating chip 80X, the insulating chip 80 of the first embodiment does not have the exposed portion 71AY. Furthermore, since the extension portion 79 is in contact with the thick insulating layer 85A—i.e., the second corner portion 74B of the second via 70B, which is prone to stress concentration, is covered with the thick insulating layer 85A—the stress between the second corner portion 74B and the thick insulating layer 85A is less likely to increase. Therefore, the risk of formation of cracks 85X as seen in the comparative insulating chip 80X can be reduced.

### Effect of First Embodiment

According to the first embodiment, the following effects are obtained.

(1-1) The insulating chip 80 includes an insulating upper surface 84S, an insulating lower surface 84R opposite to the insulating upper surface 84S, and an insulating body 84 including a plurality of insulating layers 85 laminated in the Z direction; a first via 70A provided within the insulating body 84; and a second via 70B provided within the insulating body 84 above the first via 70A. The first via 70A includes a first via upper surface 71A disposed on the insulating upper surface 84S side, a first via lower surface 72A on the opposite side of the first via upper surface 71A, and a first via side surface 73A provided between the first via upper surface 71A and the first via lower surface 72A in the Z direction. The second via 70B includes a second via upper surface 71B disposed on the insulating upper surface 84S side, and a second via lower surface 72B on the opposite side of the second via upper surface 71B, which contacts the first via upper surface 71A. The plurality of insulating layers 85 include an insulating layer 856 in which the first via 70A is embedded, and an insulating layer 857 laminated on the insulating layer 856 in which the second via 70B is embedded. Both of the insulating layers 856 and 857 include a thin insulating layer 85B formed of a material having a smaller thermal expansion coefficient than that of each of the first via 70A and the second via 70B, and a thick insulating layer 85A laminated on the thin insulating layer 85B and formed of a material having a smaller thermal expansion coefficient than that of the thin insulating layer 85B. The second via lower surface 72B of the second via 70B includes an extension portion 79 that protrudes beyond the first via upper surface 71A in a planar view. An end of the extension portion 79 is in contact with the thick insulating layer 85A of the insulating layer 857.

According to this configuration, stress concentration at the second via lower surface 72B of the second via 70B can be alleviated, and the occurrence of cracks in the thick insulating layer 85A caused by the thin insulating layer 85B can be suppressed. Therefore, reduction in the withstand voltage of the insulating chip 80 due to such cracks can be prevented.

(1-2) The first via 70A includes a first corner portion 74A provided between the first via upper surface 71A and the first via side surface 73A. The first corner portion 74A includes a recess 75. Due to the recess 75, the first via upper surface 71A becomes smaller than the second via lower surface 72B. According to this configuration, enlargement of the second via 70B in a direction orthogonal to the Z direction can be suppressed.

(1-3) The recess 75 includes a curved surface 78 that is recessed to be convex inward toward the first via 70A.

According to this configuration, due to the reverse taper shape from the first via upper surface 71A toward the first via side surface 73A formed by the recess 75, stress generated in the recess 75 acts inward toward the first via 70A. That is, stress is less likely to be applied from the recess 75 to the insulating layer 857. Therefore, occurrence of cracks in the insulating layers 856 and 857 can be suppressed. In addition, even with the recess 75 provided, excessive reduction in the area of the first via upper surface 71A can be suppressed. Thus, excessive increase in the electrical resistance of the conductive path formed by the first via 70A and the second via 70B can be suppressed.

(1-4) The cross-sectional shape of the curved surface 78 is arcuate.

According to this configuration, due to the reverse taper shape from the first via upper surface 71A toward the first via side surface 73A formed by the recess 75, stress generated in the recess 75 acts inward toward the first via 70A. That is, stress is less likely to be applied from the recess 75 to the insulating layer 857. Therefore, occurrence of cracks in the insulating layers 856 and 857 can be suppressed. In addition, even with the recess 75 provided, excessive reduction in the area of the first via upper surface 71A can be suppressed. Thus, excessive increase in the electrical resistance of the conductive path formed by the first via 70A and the second via 70B can be suppressed.

(1-5) The protruding length HA of the extension portion 79 is greater than the thickness TB of the thin insulating layer 85B of the insulating layer 856. The thin insulating layer 85B of the insulating layer 856 is in contact with a portion of the second via lower surface 72B that is inward of the second via side surface 73B.

According to this configuration, contact between the thin insulating layer 85B of the insulating layer 856 and the junction between the second via lower surface 72B and the second via side surface 73B of the second via 70B can be suppressed. Therefore, stress applied to the thin insulating layer 85B due to the stress-prone junction of the second via 70B can be suppressed. Accordingly, cracks originating in the thin insulating layer 85B can be prevented, thereby suppressing a decrease in the breakdown voltage of the insulating chip 80.

(1-6) The thick insulating layer 85A of the insulating layer 857 is in contact with the outer edge of the second via lower surface 72B and the second via side surface 73B continuous from the outer edge.

According to this configuration, the junction between the second via lower surface 72B and the second via side surface 73B is covered by the thick insulating layer 85A. That is, contact between the thin insulating layer 85B and the above junction can be suppressed. Therefore, cracks originating in the thin insulating layer 85B can be suppressed, and the breakdown voltage of the insulating chip 80 can be maintained.

(1-7) The thick insulating layer 85A of the insulating layer 857 is embedded in the recess 75. According to this configuration, the formation of voids within the recess 75 can be suppressed. Thus, cracks in the insulating layer 856 caused by such voids can be prevented.

(1-8) The thick insulating layer 85A of the insulating layer 856 includes a side surface 856A that forms the sidewall of the first through-hole 88A in which the first via 70A is embedded. The protruding length HA of the extension portion 79, at the same Z-directional position as the upper surface of the thick insulating layer 85A of the insulating layer 856, is smaller than the planar distance DC between the side surface 856A and the second via lower surface 72B.

According to this configuration, the distance between the extension portion 79 and the portion of the thin insulating layer 85B of the insulating layer 856 laminated on the thick insulating layer 85A can be increased. Therefore, the thick insulating layer 85A of the insulating layer 857 can be more easily embedded in the recess 75.

(1-9) The upper surface of the thick insulating layer 85A of the insulating layer 856 is at the same Z-directional position as the first via upper surface 71A. The thin insulating layer 85B of the insulating layer 856 includes an upper surface portion 85BA laminated on the upper surface of the thick insulating layer 85A of the insulating layer 856. The upper surface portion 85BA faces a second corner portion 74B formed by the extension portion 79 and the second via side surface 73B of the second via 70B. The upper surface portion 85BA is spaced apart from the second corner portion 74B. A thick insulating layer 85A of the insulating layer 857 is interposed between the upper surface portion 85BA and the second corner portion 74B.

According to this configuration, the thick insulating layer 85A interposed between the upper surface portion 85BA and the second corner portion 74B prevents stress from the second corner portion 74B from being easily transmitted to the upper surface portion 85BA. Therefore, peeling of the upper surface portion 85BA from the thick insulating layer 85A of the insulating layer 856 can be suppressed.

(1-10) Both the first via 70A and the second via 70B are formed so as to penetrate a plurality of thick insulating layers 85A and a plurality of thin insulating layers 85B.

Compared to a configuration in which the first via 70A penetrates only one thick insulating layer 85A and one thin insulating layer 85B, and the second via 70B likewise penetrates only one of each, greater stress is generated at the first corner portion 74A of the first via 70A and the second corner portion 74B of the second via 70B. In other words, cracks are more likely to occur in the insulating layer 856 due to this stress. However, in the insulating chip 80 of the first embodiment, the second via lower surface 72B of the second via 70B includes an extension portion 79, and the extension portion 79 is in contact with the thick insulating layer 85A of the insulating layer 857. Therefore, stress concentration at the first corner portion 74A of the first via 70A and the second corner portion 74B of the second via 70B can be alleviated, and the occurrence of cracks in the insulating layer 856 can be suppressed.

(1-11) The thickness of the first via 70A is greater than the thickness of the second via 70B. According to this configuration, even if the recess 75 is formed in the first via 70A, the area of the first via upper surface 71A is prevented from becoming excessively small. Thus, excessive increase in the electrical resistance of the conductive path formed by the first via 70A and the second via 70B can be suppressed.

### Second Embodiment

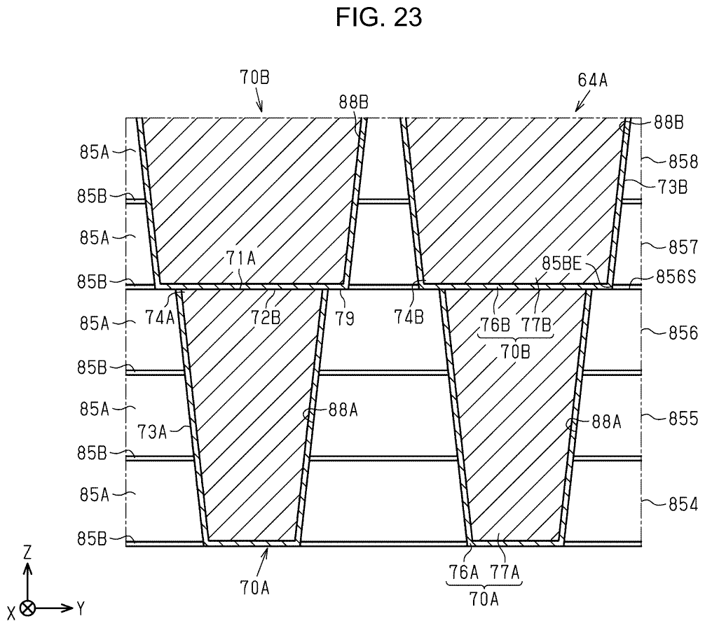

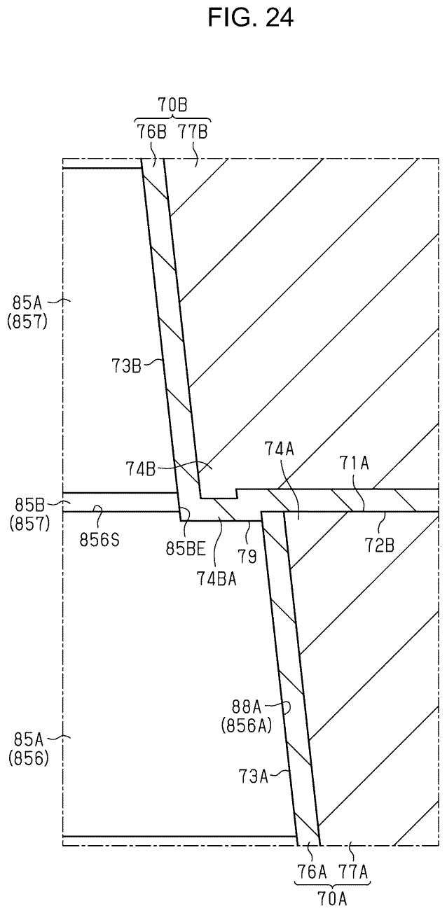

With reference to FIGS. 23 and 24, the insulating chip 80 of the second embodiment will be described.

The insulating chip 80 of the second embodiment differs primarily from the insulating chip 80 of the first embodiment in the structure of the through wiring 64A. In the following, the same reference numerals are used for components common to the first embodiment, and redundant explanation is omitted. Note that FIG. 23 omits the protruding portion 74BA (described later) for ease of understanding the drawing.

### [Structure of Through Wiring of the Insulating Chip]

FIG. 23 schematically shows an enlarged cross-sectional structure of the through wiring 64A and its periphery in the insulating chip 80 of the second embodiment.

FIG. 24 schematically shows an enlarged cross-sectional view of a portion of the through wiring 64A in FIG. 23 and its surroundings.

As shown in FIG. 23, the first via 70A of the through wiring 64A of the second embodiment does not include the recess 75 shown in FIG. 11. Accordingly, the side surface 856A forming the first through-hole 88A in the insulating layer 856 does not include the exposed side surface 85AA shown in FIG. 11. The thin insulating layer 85B of the insulating layer 856 does not include the side portion 85BB or the curved portion 85BC shown in FIG. 11.

The second via lower surface 72B of the through wiring 64A of the second embodiment is larger than the first via upper surface 71A. That is, the area of the second via lower surface 72B is larger than that of the first via upper surface 71A. In one example, the diameter of the second via lower surface 72B is greater than the diameter of the first via upper surface 71A. Thus, the second via lower surface 72B includes an extension portion 79 that protrudes beyond the first via upper surface 71A in a plan view.

In the second embodiment, the first via upper surface 71A is located at the same position in the Z direction as the upper surface 856S of the insulating layer 856. Therefore, the second via lower surface 72B, which is in contact with the first via upper surface 71A, is also located at the same Z-directional position as the upper surface 856S of the insulating layer 856.

The second via side surface 73B forming the second corner portion 74B of the second via 70B is in contact with the thin insulating layer 85B of the insulating layer 857. In other words, the side surface 85BE of the thin insulating layer 85B of the insulating layer 857 is in contact with the second via side surface 73B. The extension portion 79 is in contact with the upper surface 856S of the insulating layer 856. In this way, the second corner portion 74B is in contact with both the thick insulating layer 85A and the thin insulating layer 85B of the insulating layer 857.

As shown in FIG. 24, the second corner portion 74B includes a protruding portion 74BA that extends toward the first via lower surface 72A with respect to the first via upper surface 71A of the first via 70A. The protruding portion 74BA is annular in plan view. In the second embodiment, the protruding portion 74BA is ring-shaped in plan view. The extension portion 79 forms the lower surface of the protruding portion 74BA. As shown in FIG. 24, the protruding portion 74BA is covered by the thick insulating layer 85A of the insulating layer 856. That is, the thick insulating layer 85A of the insulating layer 856 is in contact with the extension portion 79, which constitutes the protruding portion 74BA, and extends to the second via side surface 73B. It can also be said that the end of the extension portion 79 is in contact with the thick insulating layer 85A of the insulating layer 856. Accordingly, the side surface 85BE of the thin insulating layer 85B of the insulating layer 856 is in contact with the second via side surface 73B in a state of being spaced from the extension portion 79 in the Z direction.

### [Manufacturing Method of the Through Wiring of the Insulating Chip]

The manufacturing method of the insulating chip 80 includes a step of forming the first through-hole 88A in the insulating layers 854 to 856, similarly to the first embodiment. Subsequently, the manufacturing method of the insulating chip 80 includes a step of forming the first via 70A. The step of forming the first via 70A is the same as the step of forming the conductive layer 700 in the first embodiment shown in FIG. 14.

Next, the manufacturing method of the insulating chip 80 includes a step of forming the insulating layers 857 and 858, as in the first embodiment. Subsequently, the manufacturing method includes a step of forming the second through-hole 88B in the insulating layers 857 and 858. The second through-hole 88B is formed so as to expose the entire first via upper surface 71A of the first via 70A and the upper surface of the thick insulating layer 85A of the insulating layer 856 around the first via upper surface 71A. Then, the manufacturing method includes a step of forming the second via 70B. The step of forming the second via 70B is performed in the same manner as the step of forming the first via 70A. As a result, the second via lower surface 72B of the second via 70B is in contact with the entire first via upper surface 71A exposed by the second through-hole 88B and with the upper surface of the thick insulating layer 85A of the insulating layer 856 around the first via upper surface 71A. Through the above steps, the through wiring 64A is formed.

### Effect of the Second Embodiment

According to the second embodiment, the following effects can be obtained.

(2-1) The second via 70B includes a second corner portion 74B that includes the extension portion 79 and the second via side surface 73B. The second corner portion 74B includes a protruding portion 74BA that extends toward the first via lower surface 72A with respect to the first via upper surface 71A. The extension portion 79 forms the lower surface of the protruding portion 74BA. The side surface 85BE of the thin insulating layer 85B of the insulating layer 856 is in contact with the second via side surface 73B in a state of being spaced from the extension portion 79 in the Z direction.

According to this configuration, contact between the extension portion 79 and the thin insulating layer 85B of the insulating layer 856 can be suppressed. As a result, stress from the second corner portion 74B is less likely to be applied to the thin insulating layer 85B of the insulating layer 856. Accordingly, it is possible to suppress the occurrence of cracks in the insulating layer 856 due to the thin insulating layer 85B.

### Third Embodiment

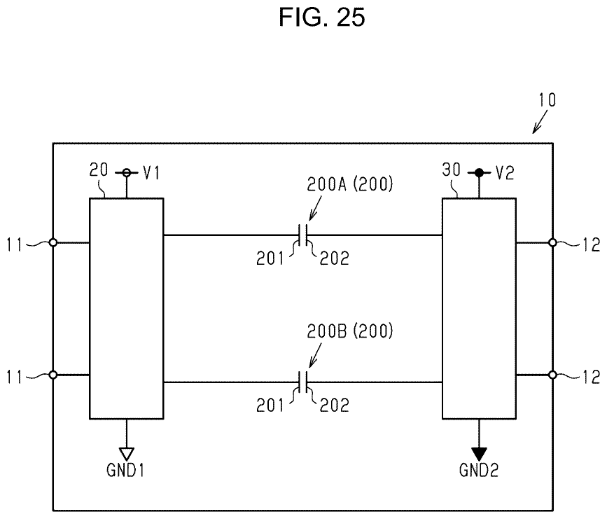

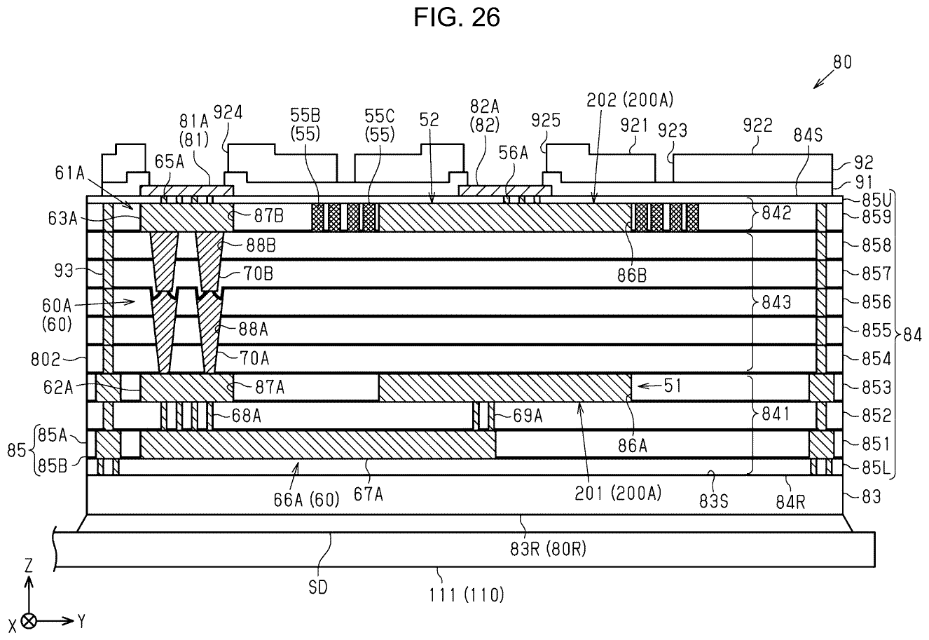

With reference to FIGS. 25 and 26, the insulating chip 80 and the signal transmission device 10 of the third embodiment will be described. In the insulating chip 80 and the signal transmission device 10 of the third embodiment, the structures of the first conductor 51 and the second conductor 52 of the insulating chip 80 mainly differ from those in the insulating chip 80 and the signal transmission device 10 of the first embodiment. In the following, the same reference numerals are used for components common to the first embodiment, and their description is omitted.

### [Configuration of the Signal Transmission Device]

FIG. 25 schematically illustrates an example of the circuit configuration of the signal transmission device 10. The signal transmission device 10 includes a capacitor 200 in place of the transformers 40A and 40B shown in FIG. 1.

As shown in FIG. 25, the signal transmission device 10 includes a capacitor 200 connected between a first circuit 20 and a second circuit 30. The signal transmission device 10 includes two capacitors 200 corresponding to the two signals transmitted between the first circuit 20 and the second circuit 30. When distinguishing the two capacitors 200, they are described as a first capacitor 200A and a second capacitor 200B.

The first circuit 20 and the second circuit 30 are connected via the first capacitor 200A and the second capacitor 200B. The signal transmission device 10 is configured to transmit signals between the first circuit 20 and the second circuit 30 via the first capacitor 200A and the second capacitor 200B.

Each of the first capacitor 200A and the second capacitor 200B includes a first electrode plate 201 and a second electrode plate 202. The first electrode plate 201 is electrically connected to the first circuit 20. The second electrode plate 202 is electrically connected to the second circuit 30.

### [Configuration of the Insulating Chip]

FIG. 26 schematically illustrates a cross-sectional structure of the insulating chip 80 according to the third embodiment. In the insulating chip 80 of the third embodiment, the primary difference from the insulating chip 80 of the first embodiment is that the first coil 41 and the second coil 42 (see FIG. 8) of the transformers 40A and 40B are replaced with a first electrode plate 201 and a second electrode plate 202.

The insulating chip 80 shown in FIG. 26 can be used in place of the insulating chip 80 shown in FIGS. 2 and 3. Therefore, a signal transmission device 10 including the insulating chip 80 of the third embodiment includes the first circuit chip 160 and the second circuit chip 170 shown in FIG. 2.

As shown in FIG. 26, the first conductor 51 of the insulating chip 80 includes the first electrode plate 201. The second conductor 52 of the insulating chip 80 includes the second electrode plate 202. Each of the first electrode plate 201 and the second electrode plate 202 is composed of a material including one or more appropriately selected from Ti, TiN, Au, Ag, Cu, Al, and W. In one example, the first electrode plate 201 and the second electrode plate 202 are composed of the same material. In another example, the first electrode plate 201 and the second electrode plate 202 may be composed of different materials.

Each of the first electrode plate 201 and the second electrode plate 202 has an elliptical shape that is elongated in the X direction in plan view. In one example, the first electrode plate 201 and the second electrode plate 202 have the same size in plan view. In another example, the first electrode plate 201 and the second electrode plate 202 may have different sizes in plan view. Note that the shape in plan view of the first electrode plate 201 and the second electrode plate 202 may be arbitrarily modified.

The first electrode plate 201 and the second electrode plate 202 face each other in the Z direction. The first electrode plate 201 is disposed near the insulating lower surface 84R of the insulating body 84. The second electrode plate 202 is disposed near the insulating upper surface 84S of the insulating body 84. A plurality of insulating layers 85 are interposed between the first electrode plate 201 and the second electrode plate 202 in the Z direction. The first electrode plate 201 is electrically connected to the first electrode pad 81 via the first connection wiring 60A. Here, the configuration of the first connection wiring 60A in the third embodiment is the same as that of the first connection wiring 60A in the first embodiment. The second electrode plate 202 is electrically connected to the second electrode pad 82 via the via wiring 56A. According to the third embodiment, the same effects as those of the first embodiment can be obtained.

### Modification Examples

Each of the above embodiments can be modified, for example, as described below. The above embodiments and the following modification examples can be combined with each other as long as no technical inconsistency arises. Note that in the following modification examples, parts that are common with the above embodiments are designated with the same reference numerals, and their descriptions are omitted.

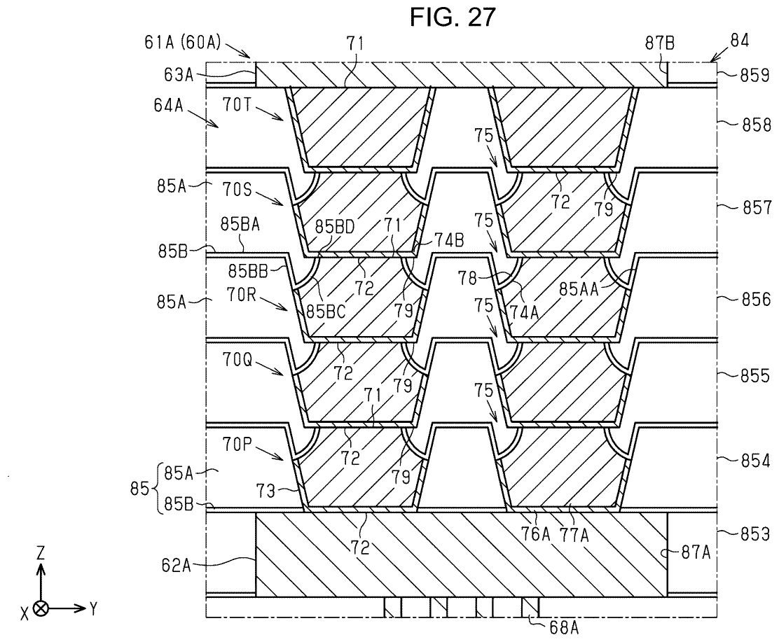

In the first embodiment, the configuration of the through wiring 64A (64B) may be modified as desired. In one example, as shown in FIG. 27, the through wiring 64A may include first to fifth vias 70P, 70Q, 70R, 70S, and 70T corresponding to the respective insulating layers 854 to 858. The first to fourth vias 70P to 70S have the same configuration and are similar to the via 70A (see FIG. 10). Therefore, the first to fourth vias 70P to 70S each include a common via upper surface 71, a via lower surface 72, and a via side surface 73. The fifth via 70T has a configuration in which the recess 75 is omitted from the first to fourth vias 70P to 70S. Accordingly, the fifth via 70T is assumed to include the via upper surface 71, the via lower surface 72, and the via side surface 73. The area of the via upper surface 71 of the fifth via 70T is larger than that of the first to fourth vias 70P to 70S due to the absence of the recess 75.

The first via 70P penetrates the insulating layer 854. The first via 70P is in contact with the first layer wiring 62A. The second via 70Q penetrates the insulating layer 855. The second via 70Q is laminated on the first via 70P. Therefore, the via lower surface 72 of the second via 70Q is in contact with the via upper surface 71 of the first via 70P. The third via 70R penetrates the insulating layer 856. The third via 70R is laminated on the second via 70Q. Therefore, the via lower surface 72 of the third via 70R is in contact with the via upper surface 71 of the second via 70Q. The fourth via 70S penetrates the insulating layer 857. The fourth via 70S is laminated on the third via 70R. Therefore, the via lower surface 72 of the fourth via 70S is in contact with the via upper surface 71 of the third via 70R. The fifth via 70T penetrates the insulating layer 858. The fifth via 70T is laminated on the fourth via 70S. Therefore, the via lower surface 72 of the fifth via 70T is in contact with the via upper surface 71 of the fourth via 70S. The via upper surface 71 of the fifth via 70T is in contact with the second layer wiring 63A.

As shown in FIG. 27, the first to fifth vias 70P to 70T include recesses 75, similar to the via 70A. The thin insulating layers 85B of the insulating layers 854 to 858 are provided along the recesses 75, similarly to the recess 75 of the via 70A. The thick insulating layer 85A of the insulating layer 855 is embedded in the recess 75 of the first via 70P. The thick insulating layer 85A of the insulating layer 856 is embedded in the recess 75 of the second via 70Q. The thick insulating layer 85A of the insulating layer 857 is embedded in the recess 75 of the third via 70R. The thick insulating layer 85A of the insulating layer 858 is embedded in the recess 75 of the fourth via 70S.

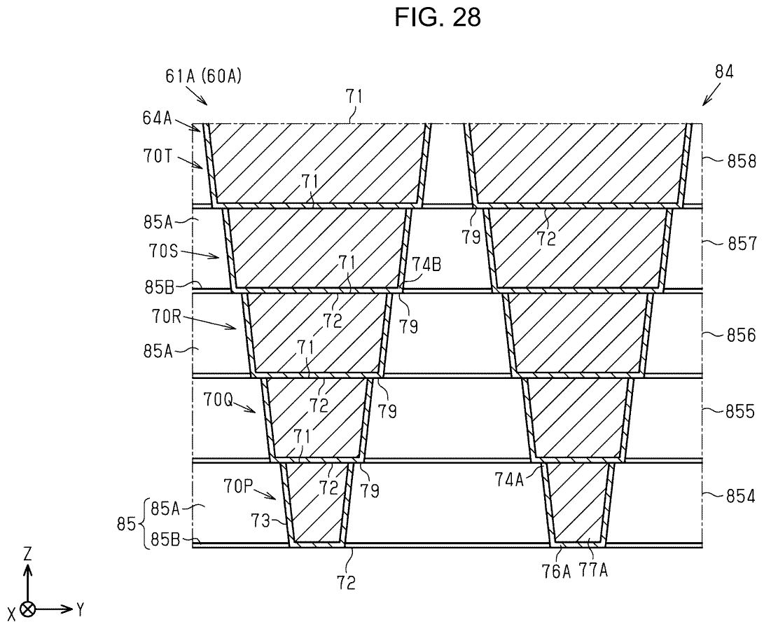

In the second embodiment, the configuration of the through wiring 64A (64B) may be modified as desired. In one example, as shown in FIG. 28, the through wiring 64A may include first to fifth vias 70P, 70Q, 70R, 70S, and 70T corresponding to the respective insulating layers 854 to 858. The stacking structure of the first to fifth vias 70P to 70T is the same as in FIG. 27.

The area of the via lower surface 72 of the second via 70Q is larger than the area of the via upper surface 71 of the first via 70P. In other words, the via lower surface 72 of the second via 70Q includes an extending portion 79 that protrudes from the via upper surface 71 of the first via 70P in a plan view. The area of the via lower surface 72 of the third via 70R is larger than the area of the via upper surface 71 of the second via 70Q. In other words, the via lower surface 72 of the third via 70R includes an extending portion 79 that protrudes from the via upper surface 71 of the second via 70Q in a plan view. The area of the via lower surface 72 of the fourth via 70S is larger than the area of the via upper surface 71 of the third via 70R. In other words, the via lower surface 72 of the fourth via 70S includes an extending portion 79 that protrudes from the via upper surface 71 of the third via 70R in a plan view. The area of the via lower surface 72 of the fifth via 70T is larger than the area of the via upper surface 71 of the fourth via 70S. In other words, the via lower surface 72 of the fifth via 70T includes an extending portion 79 that protrudes from the via upper surface 71 of the fourth via 70S in a plan view. The through wiring 64B can also be modified similarly.

In the first and second embodiments, the number of insulating layers 85 between the first layer wiring 62A and the second layer wiring 63A may be modified as desired. In one example, the number of insulating layers 85 between the first layer wiring 62A and the second layer wiring 63A may be three. In this case, the first via 70A of the through wiring 64A penetrates two insulating layers 85, and the second via 70B of the through wiring 64A penetrates one insulating layer 85.

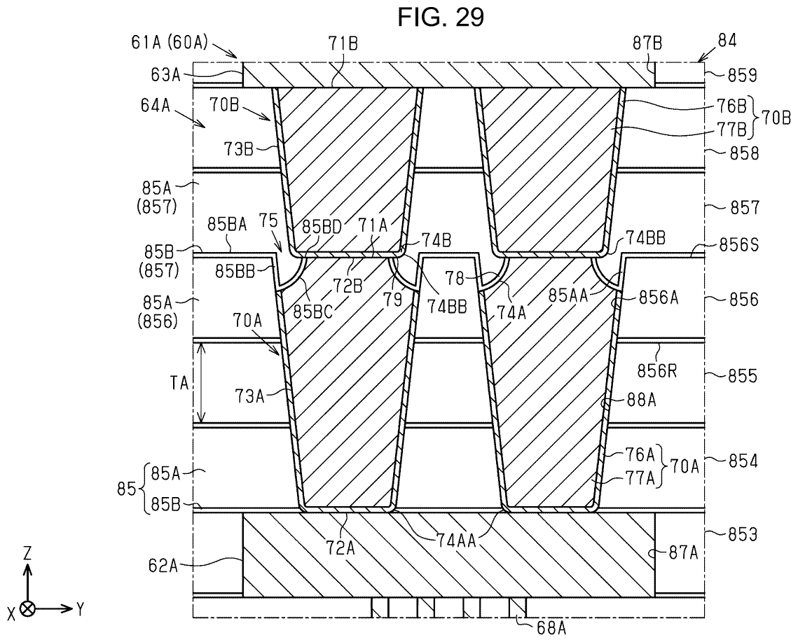

In the first embodiment, as shown in FIG. 29, the corner portion formed by the via lower surface 72A and the via side surface 73A of the first via 70A may include a curved portion 74AA. The curved portion 74AA is provided such that its center of curvature is located inward of the first via 70A. In other words, the curved portion 74AA is curved in a manner convex outward from the first via 70A. Similarly, the corner portion 74B of the second via 70B may include a curved portion 74BB. The curved portion 74BB is provided such that its center of curvature is located inward of the second via 70B. In other words, the curved portion 74BB is curved in a manner convex outward from the second via 70B.

In each of the embodiments, the structure of the first via 70A is not limited to the seed layer 76A and the plating layer 77A, and may be modified as desired. In one example, the first via 70A may be formed of a metal body embedded in the first through-hole 88A. The metal body may be made of a material including at least one of Cu and Al.

In each of the embodiments, the structure of the second via 70B is not limited to the seed layer 76B and the plating layer 77B, and may be modified as desired. In one example, the second via 70B may be formed of a metal body embedded in the second through-hole 88B. The metal body may be made of a material including at least one of Cu and Al.

In each of the embodiments, the relationship between the thickness dimension of the first via 70A and the thickness dimension of the second via 70B may be modified as desired. In one example, the thickness dimension of the first via 70A may be equal to that of the second via 70B. In another example, the thickness dimension of the first via 70A may be smaller than that of the second via 70B. In this case, for example, the first via 70A may penetrate the insulating layers 855 and 856, and the second via 70B may penetrate the insulating layers 857 to 859.

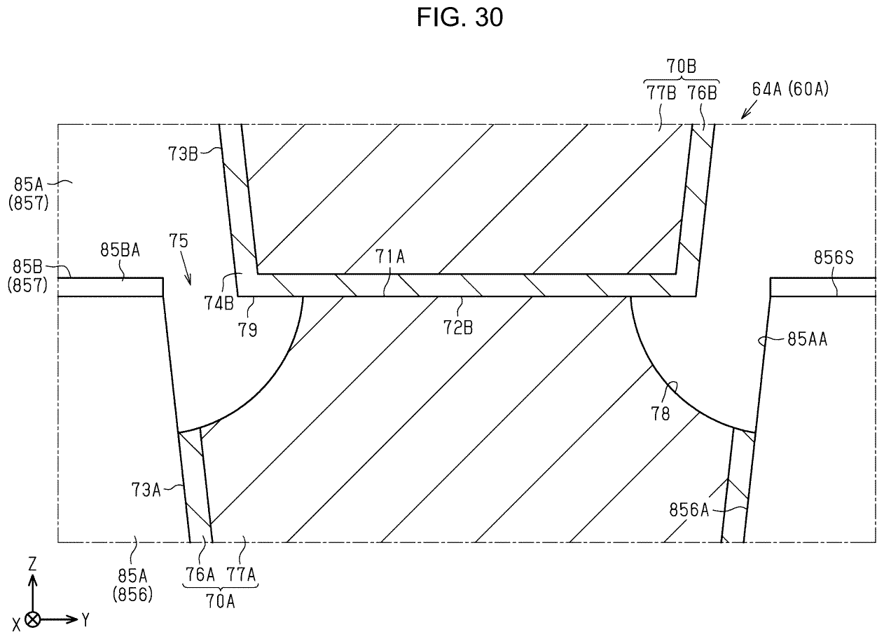

In the first embodiment, the formation range of the thin insulating layer 85B of the insulating layer 857 may be modified as desired. In one example, as shown in FIG. 30, the thin insulating layer 85B of the insulating layer 857 may not be provided along the recess 75 of the first via 70A. In this case, the thick insulating layer 85A of the insulating layer 857 is embedded so as to be in contact with the curved surface 78 of the recess 75 of the first via 70A. Also, the thin insulating layer 85B of the insulating layer 857 is spaced apart from the second via 70B. In other words, a thick insulating layer 85A of the insulating layer 857 is interposed between the thin insulating layer 85B of the insulating layer 857 and the second via 70B. According to this configuration, since a large distance can be maintained between the second corner portion 74B of the second via 70B and the exposed side surface 85AA of the insulating layer 856, the thick insulating layer 85A of the insulating layer 857 can be easily embedded within the recess 75.

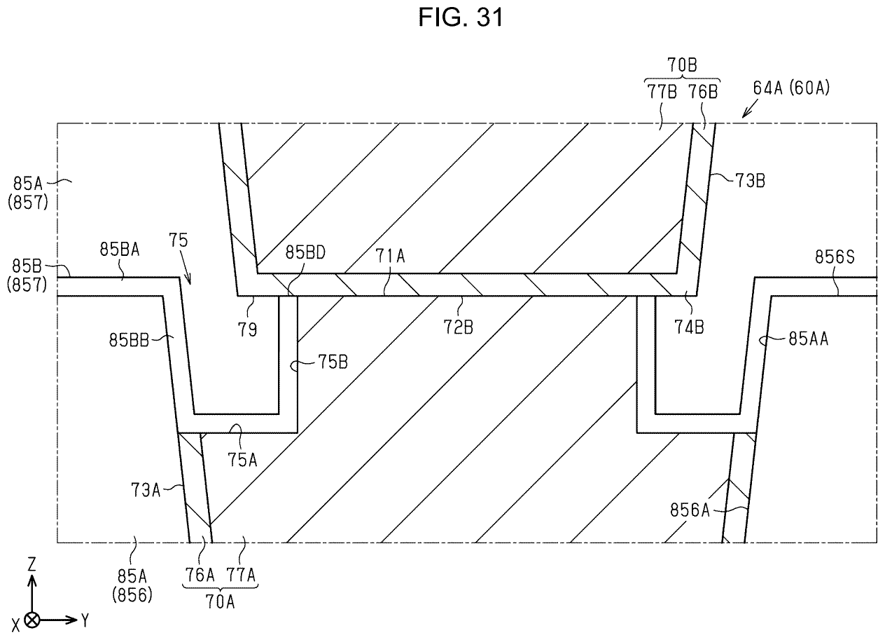

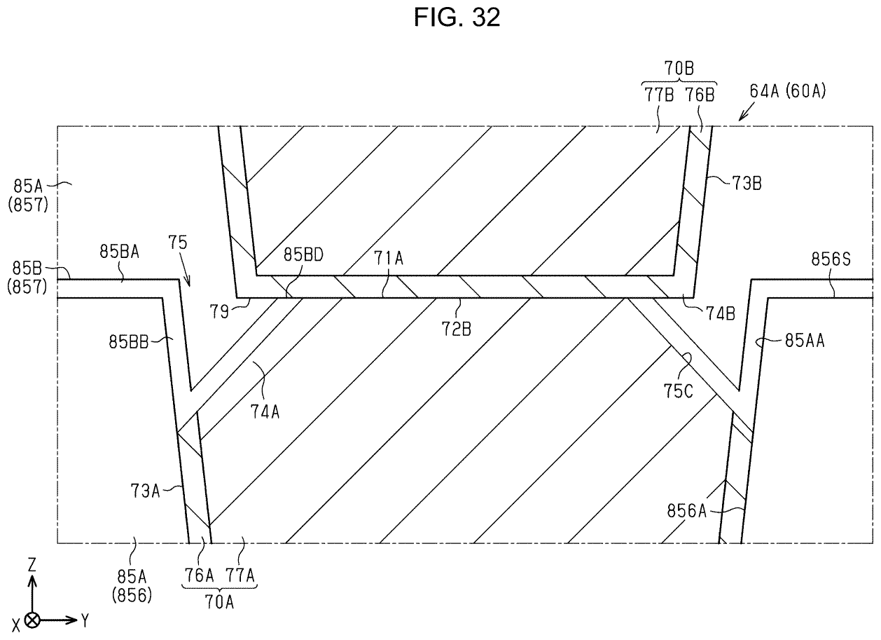

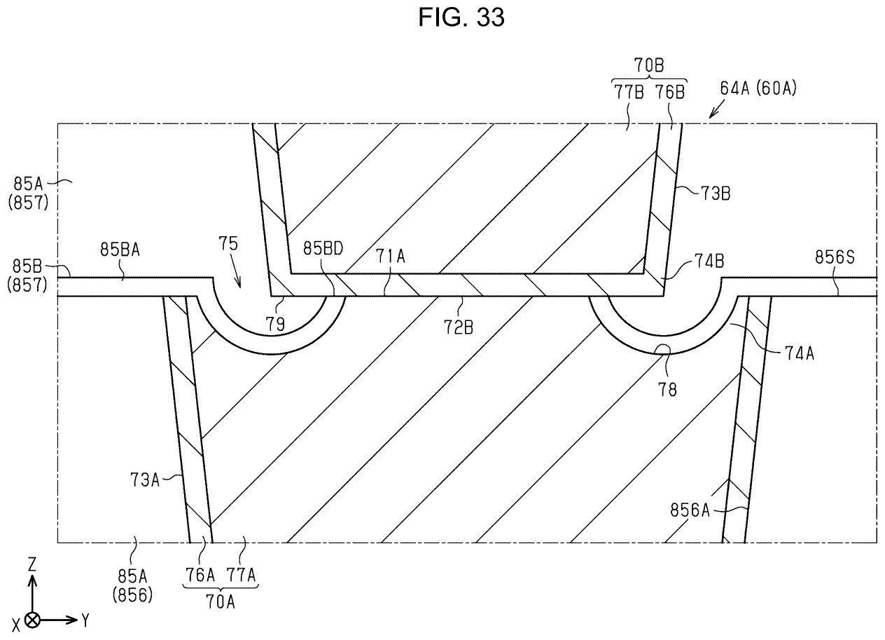

In the first embodiment, the shape of the recess 75 provided in the first corner portion 74A of the first via 70A may be modified as desired. The recess 75 may be modified, for example, as in a first example shown in FIG. 31, a second example shown in FIG. 32, or a third example shown in FIG. 33.

As shown in FIG. 31, the recess 75 of the first example may have a rectangular recessed shape. The recess 75 shown in FIG. 31 includes a bottom surface 75A and a side surface 75B. The bottom surface 75A is formed by a plane orthogonal to the Z direction. In one example, the bottom surface 75A is annular in plan view. The bottom surface 75A connects the side surface 75B and the via side surface 73A of the first via 70A. In one example, the side surface 75B is formed by a plane along the Z direction. The side surface 75B connects the bottom surface 75A and the via upper surface 71A of the first via 70A. The side surface 75B is located inward of the via lower surface 72B of the second via 70B in plan view.

The thin insulating layer 85B of the insulating layer 857 covers both the bottom surface 75A and the side surface 75B. A thick insulating layer 85A of the insulating layer 857 is embedded in the recess 75. As a result, the second corner portion 74B of the second via 70B is covered by the thick insulating layer 85A of the insulating layer 857.

The bottom surface 75A is not limited to a plane orthogonal to the Z direction and may instead be a plane that intersects the Z direction. The side surface 75B is not limited to a plane along the Z direction and may instead be a plane intersecting the Z direction. In one example, the side surface 75B may be tapered to narrow toward the via upper surface 71A of the first via 70A.

As shown in FIG. 32, the recess 75 of the second example includes an inclined surface 75C. The inclined surface 75C inclines upward from the via side surface 73A toward the via upper surface 71A of the first via 70A. The thin insulating layer 85B of the insulating layer 857 covers the inclined surface 75C. A thick insulating layer 85A of the insulating layer 857 is embedded in the recess 75. As a result, the second corner portion 74B of the second via 70B is covered by the thick insulating layer 85A of the insulating layer 857.

As shown in FIG. 33, the recess 75 of the third example may be provided at a position spaced apart from the via side surface 73A of the first via 70A. In other words, in the third example, the side surface 856A of the insulating layer 856 does not include the exposed side surface 85AA shown in FIG. 11. The recess 75 shown in FIG. 33 curves downward from the via side surface 73A of the first via 70A. The recess 75 includes a curved surface 78. In one example, the recess 75 is annular in plan view. The recess 75 is formed in the plating layer 77A of the first via 70A. On the other hand, the recess 75 is not formed in the seed layer 76A of the first via 70A. The thin insulating layer 85B of the insulating layer 857 covers the curved surface 78 of the recess 75. A thick insulating layer 85A of the insulating layer 857 is embedded in the recess 75. As a result, the second corner portion 74B of the second via 70B is covered by the thick insulating layer 85A of the insulating layer 857.

In the first embodiment, the configuration of the second via 70B may be modified as desired. In one example, the protruding length HA of the extending portion 79 may be equal to or greater than the distance DC between the side surface 856A of the insulating layer 856, which forms the side surface of the first through-hole 88A, and the via lower surface 72B of the second via 70B. In this case, a process of embedding the recess 75 with a thick insulating layer 85A may be performed prior to forming the second via 70B. In another example, the protruding length HA of the extending portion 79 may be equal to the thickness TB of the thin insulating layer 85B of the insulating layer 856.

In the second embodiment, the protruding portion 74BA may be omitted from the second corner portion 74B of the second via 70B.

In the first and second embodiments, the relationship between the thickness of the first via 70A and the thickness of the second via 70B may be arbitrarily modified. In one example, the thickness of the first via 70A may be smaller than that of the second via 70B. In another example, the thickness of the first via 70A may be equal to that of the second via 70B.

In the first and second embodiments, the shape of the first through-hole 88A may be modified as desired. In one example, the first through-hole 88A may have a constant opening area in the Z direction. That is, the side surface 856A of the insulating layer 856 may extend along the Z direction.

In the first and second embodiments, the shape of the first via 70A and the second via 70B in plan view may be arbitrarily modified. In one example, the first via 70A may have a rectangular shape in plan view. In another example, the second via 70B may have a rectangular shape in plan view. In yet another example, the first via 70A may have a polygonal shape of five or more sides in plan view. Similarly, the second via 70B may have a polygonal shape of five or more sides in plan view.

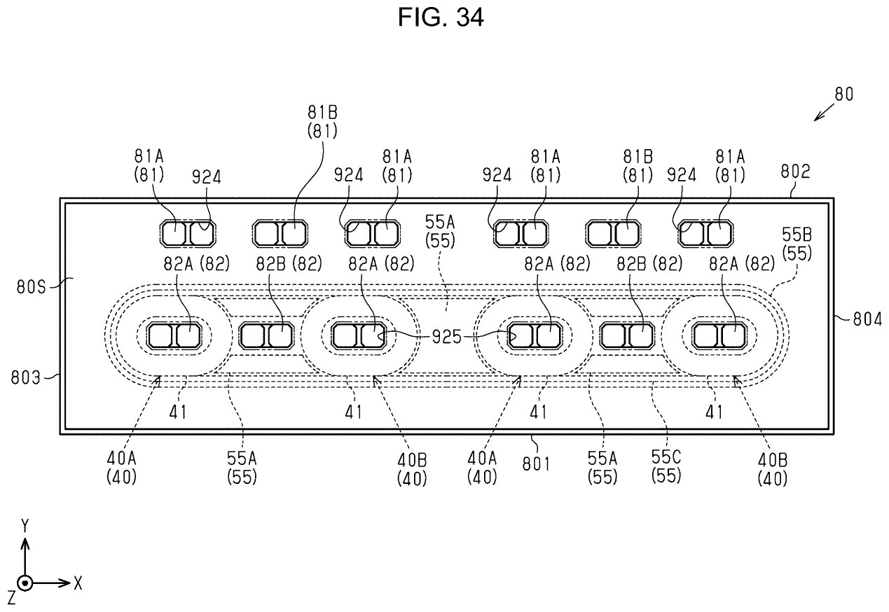

In each embodiment, the dummy pattern 55 may be omitted from the insulating chip 80. In each embodiment, the sealing portion 93 may be omitted from the insulating chip 80. In the first and second embodiments, the configuration of the insulating chip 80 may be arbitrarily modified. In one example, as shown in FIG. 34, the insulating chip 80 may include two pairs of transformers 40A and 40B. The insulating chip 80 includes a plurality of first electrode pads 81 and a plurality of second electrode pads 82 corresponding to the two pairs of transformers 40A and 40B. Each pair of transformers 40A and 40B has the same configuration and is identical to the transformers 40A and 40B of the first and second embodiments. Similar changes may also be made in the third embodiment.

In each embodiment, the configuration of the signal transmission device 10 may be arbitrarily modified.

In one example, the signal transmission device 10 may be configured to transmit signals between the first circuit chip 160 and the second circuit chip 170 via a plurality of insulating chips 80.

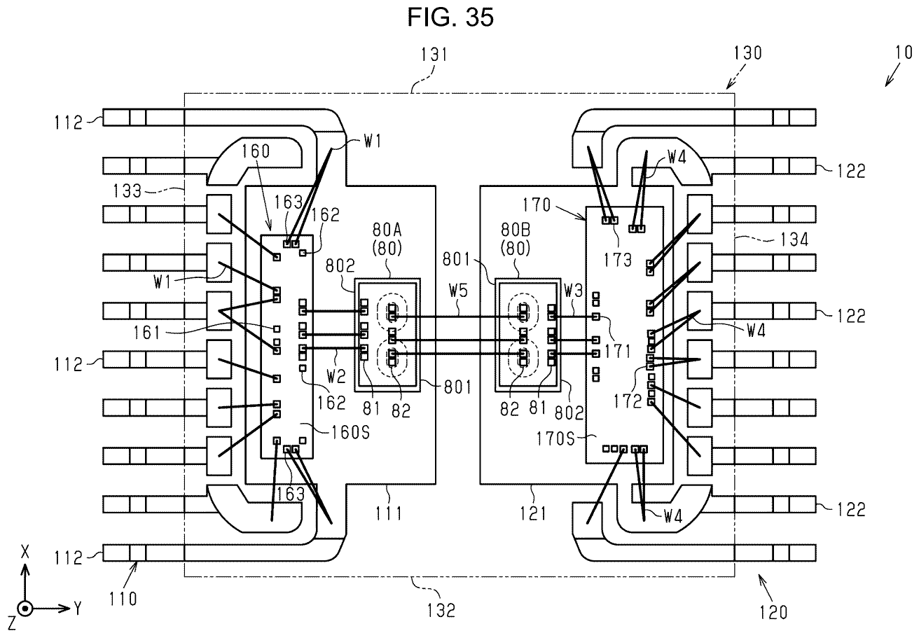

FIG. 35 schematically illustrates a plan view of the internal structure of the signal transmission device 10 according to the modification.

The modified signal transmission device 10 includes the first circuit chip 160, the second circuit chip 170, the first insulating chip 80A, and the second insulating chip 80B. In one example, the first insulating chip 80A and the second insulating chip 80B have the same configuration as the insulating chip 80. The first circuit chip 160, the second circuit chip 170, the first insulating chip 80A, and the second insulating chip 80B are arranged apart from each other in the Y direction. In the example shown in FIG. 35, the components are arranged in the order of the first circuit chip 160, the first insulating chip 80A, the second insulating chip 80B, and the second circuit chip 170 from the first lead terminal 112 toward the second lead terminal 122.

Both the first circuit chip 160 and the first insulating chip 80A are mounted on the first die pad 111. Both the second insulating chip 80B and the second circuit chip 170 are mounted on the second die pad 121.

The first electrode pad 81 of the second insulating chip 80B is electrically connected to the second circuit chip 170 via a wire W3. The second electrode pad 82 of the second insulating chip 80B is electrically connected to the second electrode pad 82 of the first insulating chip 80A via a wire W5. In other words, the first insulating chip 80A and the second insulating chip 80B are connected in series between the first circuit chip 160 and the second circuit chip 170.

Since the second insulating chip 80B has the same configuration as the first insulating chip 80A as described above, the second insulating chip 80B has the same withstand voltage as the first insulating chip 80A. Accordingly, the signal transmission device 10 has a withstand voltage corresponding to the withstand voltages of each of the serially connected first insulating chip 80A and second insulating chip 80B.

In each embodiment, at least one of the first circuit chip 160 and the second circuit chip 170 may be omitted from the signal transmission device 10.

In each embodiment, the semiconductor device is embodied as an insulating chip; however, the semiconductor device is not limited to an insulating chip. The semiconductor device may be a semiconductor chip including the first via 70A and the second via 70B provided in the plurality of insulating layers 85.

One or more of the various examples described in this specification may be combined with each other within a range where no technical contradiction arises.

The term “on” as used in this disclosure includes the meanings of both “on” and “above” unless it is clearly otherwise from the context. Accordingly, for example, the expression “the first element is mounted on the second element” is intended to mean that in some embodiments, the first element may be directly placed in contact with and on the second element, while in other embodiments, the first element may be positioned above the second element without contact. In other words, the term “on” does not exclude a structure in which another element is formed between the first element and the second element.

The Z-direction used in this disclosure does not necessarily have to be the vertical direction, and it also does not have to completely align with the vertical direction. Therefore, various structures according to the present disclosure are not limited to the “upper” and “lower” in the Z-direction described in this specification corresponding to the vertical “up” and “down.” For example, the X-direction may be the vertical direction, or the Y-direction may be the vertical direction.

### <Supplementary Note 1>

A semiconductor device (80) includes: an insulating body (84) including an insulating upper surface (84S) and an insulating lower surface (84R) opposite to the insulating upper surface (84S), and including a plurality of insulating layers (85) laminated in a thickness direction (Z); a first via (70A) provided in the insulating body (84); and a second via (70B) provided in the insulating body (84) above the first via (70A); wherein the first via (70A) includes: a first via upper surface (71A) positioned closer to the insulating upper surface (84S); a first via lower surface (72A) opposite to the first via upper surface (71A); and a first via side surface (73A) provided between the first via upper surface (71A) and the first via lower surface (72A) in the thickness direction (Z); wherein the second via (70B) includes: a second via upper surface (71B) positioned closer to the insulating upper surface (84S); and a second via lower surface (72B) opposite to the second via upper surface (71B) and in contact with the first via upper surface (71A); wherein the plurality of insulating layers (85) include: a first insulating layer (856) in which the first via (70A) is embedded; and a second insulating layer (857) laminated on the first insulating layer (856), and in which the second via (70B) is embedded; wherein each of the first insulating layer (856) and the second insulating layer (857) includes: a thin insulating layer (85B) made of a material having a smaller coefficient of thermal expansion than that of each of the first via (70A) and the second via (70B); and a thick insulating layer (85A) laminated on the thin insulating layer (85B), made of a material having a smaller coefficient of thermal expansion than the thin insulating layer (85B); wherein the second via lower surface (72B) of the second via (70B) includes, in a plan view, an extending portion (79) that protrudes beyond the first via upper surface (71A); and an end portion of the extending portion (79) is in contact with the thick insulating layer (85A) of the second insulating layer (857).

<Supplementary Note 2> In the semiconductor device of Supplementary Note 1, the first via (70A) includes a first corner portion (74A) provided between the first via upper surface (71A) and the first via side surface (73A); the first corner portion (74A) includes a recess (75); and the first via upper surface (71A) is smaller than the second via lower surface (72B) in area due to the recess (75).

<Supplementary Note 3> In the semiconductor device of Supplementary Note 2, the recess (75) includes a curved surface (78) recessed so as to be convex inward toward the first via (70A).

<Supplementary Note 4> In the semiconductor device of Supplementary Note 3, the cross-sectional shape of the curved surface (78) is arcuate.

<Supplementary Note 5> In the semiconductor device of Supplementary Note 3 or 4, the thin insulating layer (85B) of the second insulating layer (857) is in contact with the curved surface (78).

<Supplementary Note 6> In the semiconductor device of any one of Supplementary Notes 2 to 5, the second via (70B) includes a second via side surface (73B) connecting the second via upper surface (71B) and the second via lower surface (72B); an overhang length (HA) of the extending portion (79) is greater than a thickness (TB) of the thin insulating layer (85B) of the second insulating layer (857); and the thin insulating layer (85B) of the second insulating layer (857) is in contact with a portion of the second via lower surface (72B) that is inward of the second via side surface (73B).

<Supplementary Note 7> In the semiconductor device of Supplementary Note 6, the thick insulating layer (85A) of the second insulating layer (857) is in contact with an outer edge of the second via lower surface (72B) and the second via side surface (73B) continuous from the outer edge.

<Supplementary Note 8> In the semiconductor device of Supplementary Note 7, the thick insulating layer (85A) of the second insulating layer (857) is embedded in the recess (75).

<Supplementary Note 9> In the semiconductor device of any one of Supplementary Notes 6 to 8, the first insulating layer (856) includes a side surface (856A) that constitutes the through-hole (88A) in which the first via (70A) is embedded; and the overhang length (HA) of the extending portion (79) is located at the same position as an upper surface (856S) of the first insulating layer (856) in the thickness direction (Z) and is smaller than a distance (DC) in a plan view between the side surface (856A) and the second via lower surface (72B).

<Supplementary Note 10> In the semiconductor device of Supplementary Note 9, an upper surface (856S) of the first insulating layer (856) is located at the same position in the thickness direction (Z) as the first via upper surface (71A); the thin insulating layer (85B) of the second insulating layer (857) includes an upper surface portion (85BA) stacked on the upper surface (856S) of the first insulating layer (856); and the upper surface portion (85BA) faces a second corner portion (74B) of the second via (70B) formed by the extending portion (79) and the second via side surface (73B).

<Supplementary Note 11> In the semiconductor device of Supplementary Note 10, the upper surface portion (85BA) is spaced apart from the second corner portion (74B); and the thick insulating layer (85A) of the second insulating layer (857) is interposed between the upper surface portion (85BA) and the second corner portion (74B).

<Supplementary Note 12> In the semiconductor device of any one of Supplementary Notes 9 to 11, the side surface (856A) of the first insulating layer (856) is inclined such that an opening area of the through-hole (88A) decreases from the upper surface (856S) of the first insulating layer (856) to a lower surface (856R) of the first insulating layer (856) in the thickness direction (Z); and the first via side surface (73A) is provided along the side surface (856A) of the first insulating layer (856).

<Supplementary Note 13> In the semiconductor device of Supplementary Note 12, the side surface (856A) of the first insulating layer (856) includes an exposed side surface (85AA) that is exposed from the first via side surface (73A) by the recess (75); and the thin insulating layer (85B) of the second insulating layer (857) is provided along the exposed side surface (85AA).

<Supplementary Note 14> In the semiconductor device of any one of Supplementary Notes 2 to 13, the first via (70A) includes the seed layer (76A) and a plating layer (77A) provided on the seed layer (76A); and the recess (75) is provided across both the seed layer (76A) and the plating layer (77A).

<Supplementary Note 15> In the semiconductor device of Supplementary Note 1, the second via (70B) includes a second via side surface (73B) connecting the second via upper surface (71B) and the second via lower surface (72B), and a second corner portion (74B) including the extending portion (79) and the second via side surface (73B); the second corner portion (74B) includes a protruding portion (74BA) extending toward the first via lower surface (72A) relative to the first via upper surface (71A); the extending portion (79) constitutes a lower surface of the protruding portion (74BA); and a side surface (85BE) of the thin insulating layer (85B) of the second insulating layer (857) is in contact with the second via side surface (73B) in a state spaced apart from the extending portion (79) in the thickness direction (Z).

<Supplementary Note 16> In the semiconductor device of Supplementary Note 15, the thick insulating layer (85A) of the first insulating layer (856) is in contact with an entire span from the extending portion (79) constituting the protruding portion (74BA) to the second via side surface (73B).

<Supplementary Note 17> In the semiconductor device of any one of Supplementary Notes 1 to 16, both the first via (70A) and the second via (70B) are provided so as to penetrate through a plurality of the thick insulating layers (85A) and a plurality of the thin insulating layers (85B).

<Supplementary Note 18> In the semiconductor device of Supplementary Note 17, a thickness of the first via (70A) is greater than a thickness of the second via (70B).

<Supplementary Note 19> In the semiconductor device of any one of Supplementary Notes 1 to 18, the thick insulating layer (85A) is made of a material including SiO, and the thin insulating layer (85B) is made of a material including SiN.

<Supplementary Note 20> In the semiconductor device of any one of Supplementary Notes 1 to 19, the semiconductor device includes a first conductor (51) disposed closer to the insulating lower surface (84R) in the insulating body (84); a second conductor (52) disposed in the insulating body (84) closer to the insulating upper surface (84S) than the first conductor (51) and facing the first conductor (51) in the thickness direction (Z); a first electrode pad (81) electrically connected to the first conductor (51); a second electrode pad (82) electrically connected to the second conductor (52); and a connection wiring (60) provided in the insulating body (84) and connecting the first conductor (51) and the first electrode pad (81); the connection wiring (60) includes a first wiring portion (61A) extending in the thickness direction (Z) and connected to the first electrode pad (81), and a second wiring portion (66A) connected to the first conductor (51) and extending outward from the first conductor (51) in a plan view; the first wiring portion (61A) includes a first layer wiring (62A) provided at the same position in the thickness direction (Z) as the first conductor (51) and electrically connected to the second wiring portion (66A), a second layer wiring (63A) provided at the same position in the thickness direction (Z) as the second conductor (52), a through wiring (64A) provided between the first layer wiring (62A) and the second layer wiring (63A) in the thickness direction (Z), and a surface-side via wiring (65A) connecting the second layer wiring (63A) and the first electrode pad (81); and the through wiring (64A) includes the first via (70A) and the second via (70B).

<Supplementary Note 21> In the semiconductor device of Supplementary Note 20, the second wiring portion (66A) is disposed across the first conductor (51) from the second conductor (52) in the thickness direction (Z); and the second wiring portion (66A) includes a lead-out wiring (67A) extending in a direction orthogonal to the thickness direction (Z), a first back-side via wiring (68A) connecting the first layer wiring (62A) and the lead-out wiring (67A), and a second back-side via wiring (69A) connecting the first conductor (51) and the lead-out wiring (67A).

<Supplementary Note 22> In the semiconductor device of Supplementary Note 20 or 21, both the first conductor (51) and the second conductor (52) include coils (41/42).

<Supplementary Note 23> In the semiconductor device of Supplementary Note 22, the first electrode pad (81) includes a first pad (81A) and a second pad (81B); the first conductor (51) includes a first coil (41); and the connection wiring (60) includes a first connection wiring (60A) electrically connecting the first pad (81A) and the first coil (41), and a second connection wiring (60B) electrically connecting the second pad (81B) and the first coil (41).

<Supplementary Note 24> In the semiconductor device of Supplementary Note 23, the first conductor (51) includes an inner terminal wiring (51A) connected to a first end of the first coil (41), and an outer terminal wiring (51B) connected to a second end of the first coil (41); the first connection wiring (60A) connects the inner terminal wiring (51A) and the first pad (81A); and the second connection wiring (60B) connects the outer terminal wiring (51B) and the second pad (81B).

<Supplementary Note 25> In the semiconductor device of Supplementary Note 20 or 21, both the first conductor (51) and the second conductor (52) include electrode plates (201/202).

<Supplementary Note 26> A semiconductor device (80) including an insulating body (84) having an insulating upper surface (84S) and an insulating lower surface (84R) opposite to the insulating upper surface (84S), and including a plurality of insulating layers (85) laminated in a thickness direction (Z); a first via (70A) provided in the insulating body (84); and a second via (70B) provided in the insulating body (84) on the first via (70A); the plurality of insulating layers (85) include a first insulating layer (856) in which the first via (70A) is embedded, and a second insulating layer (857) laminated on the first insulating layer (856) and in which the second via (70B) is embedded; both the first insulating layer (856) and the second insulating layer (857) include a thin insulating layer (85B) made of a material having a lower coefficient of thermal expansion than each of the first via (70A) and the second via (70B), and a thick insulating layer (85A) made of a material different from that of the thin insulating layer (85B) and laminated on the thin insulating layer (85B); the first via (70A) includes a first via upper surface (71A) disposed closer to the insulating upper surface (84S), a first via lower surface (72A) opposite to the first via upper surface (71A), and a first via side surface (73A) provided between the first via upper surface (71A) and the first via lower surface (72A) in the thickness direction (Z); the second via (70B) includes a second via upper surface (71B) disposed closer to the insulating upper surface (84S), and a second via lower surface (72B) disposed on the opposite side to the second via upper surface (71B) and contacting the first via upper surface (71A); the second via lower surface (72B) of the second via (70B) includes an extending portion (79) protruding from the first via upper surface (71A) in a plan view; and an end of the extending portion (79) is in contact with the thick insulating layer (85A) of the second insulating layer (857).

<Supplementary Note 27> In the semiconductor device of Supplementary Note 26, the coefficient of thermal expansion of the thick insulating layer (85A) is smaller than that of the thin insulating layer (85B).

<Supplementary Note 28> In the semiconductor device of Supplementary Note 27, the thick insulating layer (85A) is made of a material including SiO, and the thin insulating layer (85B) is made of a material including SiN.

<Supplementary Note 29> In the semiconductor device of any one of Supplementary Notes 26 to 28, the first via (70A) includes a seed layer (76A) and a plating layer (77A) provided on the seed layer (76A); and the second via lower surface (72B) is in contact with both the seed layer (76A) and the plating layer (77A) of the first via (70A).

<Supplementary Note 30> In the semiconductor device of any one of Supplementary Notes 26 to 29, the second via (70B) includes a seed layer (76B) and a plating layer (77B) provided on the seed layer (76B); and a side surface (85BE) of the thin insulating layer (85B) of the second insulating layer (857) is in contact with the seed layer (76B) of the second via (70B).

<Supplementary Note 31> In the semiconductor device of any one of Supplementary Notes 1 to 30, the first via (70A) has a circular shape in a plan view.

<Supplementary Note 32> In the semiconductor device of any one of Supplementary Notes 1 to 30, the first via (70A) has a quadrilateral shape in a plan view.

<Supplementary Note 33> In the semiconductor device of any one of Supplementary Notes 1 to 32, the first via (70A) and the second via (70B) are made of the same material.

<Supplementary Note 34> In the semiconductor device of any one of Supplementary Notes 1 to 32, the first via (70A) and the second via (70B) are made of different materials.

<Supplementary Note 35> A semiconductor module (10) including the semiconductor device (80) according to any one of Supplementary Notes 1 to 34, a first die pad (111) on which the semiconductor device (80) is mounted, and a sealing resin (130) sealing in the semiconductor device (80) and the first die pad (111).

<Supplementary Note 36> A signal transmission device (10) including the semiconductor device (80) according to any one of Supplementary Notes 20 to 25, and a first circuit (20) and a second circuit (30) electrically connected to the semiconductor device (80); wherein the first circuit (20) and the second circuit (30) are configured to transmit signals through the semiconductor device (80).

<Supplementary Note 37> A method of manufacturing a semiconductor device (80) including: forming an insulating body (84) having an insulating upper surface (84S) and an insulating lower surface (84R) opposite to the insulating upper surface (84S), and including a plurality of insulating layers (85) laminated in a thickness direction (Z); forming a first via (70A) in the insulating body (84); and forming a second via (70B) on the first via (70A) in the insulating body (84); the first via (70A) includes a first via upper surface (71A) disposed closer to the insulating upper surface (84S), a first via lower surface (72A) opposite to the first via upper surface (71A), and a first via side surface (73A) provided between the first via upper surface (71A) and the first via lower surface (72A) in the thickness direction (Z); the second via (70B) includes a second via upper surface (71B) disposed closer to the insulating upper surface (84S), and a second via lower surface (72B) disposed on the opposite side to the second via upper surface (71B) and contacting the first via upper surface (71A); the plurality of insulating layers (85) include a first insulating layer (856) in which the first via (70A) is embedded and a second insulating layer (857) laminated on the first insulating layer (856) in which the second via (70B) is embedded; both the first insulating layer (856) and the second insulating layer (857) include a thin insulating layer (85B) made of a material having a lower coefficient of thermal expansion than each of the first via (70A) and the second via (70B), and a thick insulating layer (85A) made of a material having a lower coefficient of thermal expansion than the thin insulating layer (85B) and laminated on the thin insulating layer (85B); forming the second via (70B) includes forming the second via (70B) so that the second via lower surface (72B) includes an extending portion (79) that protrudes from the first via upper surface (71A) in a plan view; and forming the insulating body (84) includes forming the thick insulating layer (85A) of the second insulating layer (857) so that the thick insulating layer (85A) of the second insulating layer (857) contacts an end of the extending portion (79).

<Supplementary Note 38> In the method of manufacturing a semiconductor device of Supplementary Note 37, forming the first via (70A) is performed after forming the first insulating layer (856) and before forming the second insulating layer (857); and forming the first via (70A) includes: forming a first through hole (88A) in the first insulating layer (856); forming a conductive layer (700) in the first through hole (88A); etching the thick insulating layer (85A) of the first insulating layer (856) to cause the conductive layer (700) to protrude from the thick insulating layer (85A); and isotropically etching the conductive layer (700) to remove the portion of the conductive layer (700) protruding from the thick insulating layer (85A) and to form a recess (75).

<Supplementary Note 39> In the method of manufacturing a semiconductor device of Supplementary Note 38, forming the insulating body (84) includes forming the thin insulating layer (85B) of the second insulating layer (857); and forming the thin insulating layer (85B) of the second insulating layer (857) includes: forming the thin insulating layer (85B) so as to cover the thick insulating layer (85A) of the first insulating layer (856), the recess (75) of the first via (70A), and the first via upper surface (71A); and removing the portion of the thin insulating layer (85B) that covers the first via upper surface (71A).

<Supplementary Note 40> In the method of manufacturing a semiconductor device of Supplementary Note 39, forming the insulating body (84) includes forming the thick insulating layer (85A) of the second insulating layer (857); and forming the thick insulating layer (85A) of the second insulating layer (857) includes embedding the thick insulating layer (85A) in the recess (75).

The above description is merely illustrative. A person skilled in the art will recognize that, in addition to the elements and methods (manufacturing processes) listed for the purpose of describing the technology of the present disclosure, many more conceivable combinations and substitutions are possible. The present disclosure is intended to encompass all alternatives, modifications, and variations included within the scope of the present disclosure including the claims.

What is claimed is:

1. A semiconductor device, comprising:
an insulating body having an insulating upper surface and an insulating lower surface opposite to the insulating upper surface, and including a plurality of insulating layers laminated in a thickness direction;
a first via provided within the insulating body; and
a second via provided within the insulating body above the first via, wherein:
the first via includes a first via upper surface disposed on an insulating upper surface side, a first via lower surface opposite to the first via upper surface, and a first via side surface provided between the first via upper surface and the first via lower surface in the thickness direction;
the second via includes a second via upper surface disposed on the insulating upper surface side and a second via lower surface on an opposite side of the second via upper surface and in contact with the first via upper surface;
the plurality of insulating layers includes a first insulating layer in which the first via is embedded and a second insulating layer laminated on the first insulating layer in which the second via is embedded;
both the first and second insulating layers include a thin insulating layer made of a material having a lower coefficient of thermal expansion than a coefficient of thermal expansion of each of the first and second vias, and a thick insulating layer made of a material having a lower coefficient of thermal expansion than a coefficient of thermal expansion of the thin insulating layer and laminated on the thin insulating layer;
the second via lower surface includes an extension portion protruding beyond the first via upper surface in plan view; and
an end portion of the extension portion is in contact with the thick insulating layer of the second insulating layer.

2. The semiconductor device according to claim 1, wherein:
the first via includes a first corner portion provided between the first via upper surface and the first via side surface;
the first corner portion includes a recess; and
the first via upper surface is smaller than the second via lower surface in area in plan view due to the recess.

3. The semiconductor device according to claim 2, wherein the recess includes a curved surface recessed in a manner convex inward toward the first via.

4. The semiconductor device according to claim 3, wherein a cross-sectional shape of the curved surface is an arc shape.

5. The semiconductor device according to claim 3, wherein the thin insulating layer of the second insulating layer is in contact with the curved surface.

6. The semiconductor device according to claim 2, wherein:
the second via includes a second via side surface connecting the second via upper surface and the second via lower surface;
a protruding length of the extension portion is greater than a thickness of the thin insulating layer of the second insulating layer; and
the thin insulating layer of the second insulating layer is in contact with a portion of the second via lower surface inward of the second via side surface.

7. The semiconductor device according to claim 6, wherein the thick insulating layer of the second insulating layer is in contact with an outer edge of the second via lower surface and with the second via side surface, the second via side surface being continuous from the outer edge.

8. The semiconductor device according to claim 7, wherein the thick insulating layer of the second insulating layer is embedded in the recess.

9. The semiconductor device according to claim 6, wherein:
the first insulating layer includes a side surface forming a through-hole in which the first via is embedded; and
the protruding length of the extension portion is at a position in the thickness direction aligned with an upper surface of the first insulating layer and is smaller than a distance, in plan view, between the side surface and the second via lower surface.

10. The semiconductor device according to claim 9, wherein:
the upper surface of the first insulating layer is at a position in the thickness direction aligned with the first via upper surface;
the thin insulating layer of the second insulating layer includes an upper portion laminated on the upper surface of the first insulating layer; and
the upper portion faces a second corner portion formed by the extension portion and the second via side surface of the second via.

11. The semiconductor device according to claim 10, wherein:
the upper portion is spaced apart from the second corner portion; and
the thick insulating layer of the second insulating layer is interposed between the upper portion and the second corner portion.

12. The semiconductor device according to claim 9, wherein:
the side surface of the first insulating layer is inclined such that an opening area of the through-hole becomes smaller from the upper surface of the first insulating layer toward a lower surface of the first insulating layer; and
the first via side surface is provided along the side surface of the first insulating layer.

13. The semiconductor device according to claim 12, wherein the side surface of the first insulating layer includes an exposed side surface exposed from the first via side surface by the recess; and
the thin insulating layer of the second insulating layer is provided along the exposed side surface.

14. The semiconductor device according to claim 1, wherein:
the second via includes a second via side surface connecting the second via upper surface and the second via lower surface, and a second corner portion including the extension portion and the second via side surface;
the second corner portion includes a protruding portion extending toward a first via lower surface side with respect to the first via upper surface;
the extension portion forms a lower surface of the protruding portion; and
a side surface of the thin insulating layer of the second insulating layer is in contact with the second via side surface in a state separated from the extension portion in the thickness direction.

15. The semiconductor device according to claim 14, wherein the thick insulating layer of the first insulating layer is in contact with the extension portion forming the protruding portion and extends to the second via side surface.

16. The semiconductor device according to claim 1, wherein both the first via and the second via are provided to penetrate a plurality of the thick insulating layers and a plurality of the thin insulating layers.

17. The semiconductor device according to claim 16, wherein a thickness dimension of the first via is greater than a thickness dimension of the second via.

18. The semiconductor device according to claim 1, wherein the thick insulating layer is formed of a material including SiO, and the thin insulating layer is formed of a material including SiN.

19. The semiconductor device according to claim 1, further comprising:
a first conductor disposed closer to the insulating lower surface than to the insulating upper surface within the insulating body;
a second conductor disposed closer to the insulating upper surface than to the first conductor within the insulating body, and facing the first conductor in the thickness direction;
a first electrode pad electrically connected to the first conductor;
a second electrode pad electrically connected to the second conductor; and
a connection wiring provided within the insulating body and connecting the first conductor and the first electrode pad, wherein
the connection wiring includes:
a first wiring portion connected to the first electrode pad and extending in the thickness direction; and
a second wiring portion connected to the first conductor and extending outward beyond the first conductor in plan view,
the first wiring portion including:
a first-layer wiring provided at a same position in the thickness direction as a position of the first conductor and electrically connected to the second wiring portion;
a second-layer wiring provided at a same position in the thickness direction as a position the second conductor;
a through wiring provided between the first-layer wiring and the second-layer wiring in the thickness direction; and
a surface-side via wiring connecting the second-layer wiring and the first electrode pad, and
the through wiring includes the first via and the second via.

20. A signal transmission device, comprising:
the semiconductor device according to claim 19; and
a first circuit and a second circuit electrically connected to the semiconductor device, wherein
the first circuit and the second circuit are configured to transmit a signal via the semiconductor device.
